(19) United States
(12) Patent Application Publication
(10) Pub. No.: US 2025/0056989 A1
(43) Pub. Date: Feb. 13, 2025

(54) DISPLAY DEVICE

(71) Applicant: Samsung Display Co., LTD., Yongin-si (KR)

(72) Inventors: HANBUM KWON, Yongin-si (KR); EUNBYUL KIM, Yongin-si (KR); YOUNGMIN AHN, Yongin-si (KR)

(21) Appl. No.: 18/780,598

(22) Filed: Jul. 23, 2024

(30) Foreign Application Priority Data
Aug. 9, 2023 (KR) 10-2023-0103981

(51) Int. Cl. H10K 59/131; H10K 59/124

(52) U.S. Cl. CPC H10K 59/131; H10K 59/124

(57) ABSTRACT

A display device including a display panel that includes a pad electrode, a data driver disposed on the display panel and including a bump electrode that corresponds to the pad electrode, and an adhesive layer that includes a nano-conductive particle in contact with the pad electrode and the bump electrode. The pad electrode includes a dielectric pattern that protrudes more than the surroundings of the pad electrode, a conductive pattern that covers the dielectric pattern, and a dielectric layer that covers the conductive pattern. The nano-conductive particle penetrates the dielectric layer to contact the conductive pattern.

This application claims priority to Korean Patent Application No. 10-2023-0103981, filed on Aug. 9, 2023, and all the benefits accruing therefrom under 35 U.S.C. § 119, the content of which in its entirety is herein incorporated by reference.

### BACKGROUND

### 1. Field

The present invention relates to a display device, and more particularly to a display device having improved properties of electrical connection between a pad electrode and a data driver.

### 2. Description of the Related Art

Electronic products such as smart phones, digital cameras, laptop computers, navigation systems, and smart televisions include a display device for displaying an image to users. The display device generates an image and provides users with the image displayed on a display screen.

The display device includes a display panel that displays an image. The display panel includes a plurality of gate lines, a plurality of data lines, and a plurality of pixels connected to the plurality of gate lines and the plurality of data lines.

The display panel may be connected to a data driver that provides the gate lines or the data lines with electrical signals required for displaying images.

### SUMMARY

An embodiment of the invention provides a display device which has improved properties of electrical connection between a pad electrode and a data driver and which requires a reduced time for forming a pad electrode.

According to an embodiment, a display device may include a display panel that includes a pad electrode, a data driver on the display panel, the data driver including a bump electrode that corresponds to the pad electrode and an adhesive layer that includes a nano-conductive particle in contact with the pad electrode and the bump electrode. The pad electrode may include a dielectric pattern that protrudes more than the surroundings of the pad electrode, a conductive pattern that covers the dielectric pattern and a dielectric layer that covers the conductive pattern. The nano-conductive particle may penetrate the dielectric layer to contact the conductive pattern.

In an embodiment, a diameter of the nano-conductive particle may be in a range of about 50 nanometers to about 100 nanometers.

In an embodiment, the pad electrode and the bump electrode may be electrically connected to each other through the nano-conductive particle.

In an embodiment, the adhesive layer may further include an adhesive resin. The nano-conductive particle may be provided in plural, and the plurality of nano-conductive particles may be uniformly distributed in the adhesive resin.

In an embodiment, the adhesive layer may further include an adhesive resin. The nano-conductive particle may be disposed between a bottom surface of the data driver, the pad electrode, and the bump electrode.

In an embodiment, the diameter of the nano-conductive particle may be greater than a thickness of the dielectric layer.

In an embodiment, the thickness of the dielectric layer may be in a range of about 10 nanometers to about 30 nanometers.

In an embodiment, the pad electrode may have a flat top surface that faces the bump electrode.

In an embodiment, the conductive pattern may include a first conductive pattern disposed below the dielectric pattern, a second conductive pattern disposed between the first conductive pattern and the dielectric pattern, a third conductive pattern that covers the dielectric pattern and is connected to the second conductive pattern and a fourth conductive pattern on the third conductive pattern. The dielectric pattern may protrude more than the surroundings of the pad electrode. The third conductive pattern and the fourth conductive pattern on the dielectric pattern may protrude more than surroundings of the pad electrode.

In an embodiment, the data driver may further include an integrated circuit disposed on and connected to the bump electrode.

In an embodiment, the nano-conductive particle may include one of chromium and molybdenum.

According to an embodiment, a display device may include a base substrate, a pad electrode including a plurality of conductive patterns that reside on the base substrate and a dielectric layer that covers the conductive patterns, a data driver including a bump electrode that corresponds to the pad electrode and an adhesive layer disposed between the pad electrode and the bump electrode, the adhesive layer including a plurality of nano-conductive particles. The nano-conductive particles in contact with the conductive patterns may be surrounded by the dielectric layer.

In an embodiment, the nano-conductive particles may penetrate the dielectric layer to come into contact with the conductive patterns. The nano-conductive particles may be in contact with the bump electrode. The bump electrode and the conductive pattern may be electrically connected to each other through the nano-conductive particles.

In an embodiment, a diameter of the nano-conductive particle may be in a range of about 50 nanometers to about 100 nanometers.

In an embodiment, the adhesive layer may further include an adhesive resin. The nano-conductive particles may be uniformly distributed in the adhesive resin.

In an embodiment, the nano-conductive particles may be disposed between a bottom surface of the data driver, the pad electrode, and the bump electrode.

In an embodiment, the conductive patterns may include a first conductive pattern, a second conductive pattern disposed on and connected to the first conductive pattern, a third conductive pattern disposed on and connected to the second conductive pattern, and a fourth conductive pattern disposed on and connected to the third conductive pattern. The dielectric layer may be disposed on a top surface of the fourth conductive pattern.

In an embodiment, the pad electrode may further include a dielectric pattern disposed between the second conductive pattern and the third conductive pattern. The dielectric pattern may cause the third conductive pattern and the fourth conductive pattern to protrude more than the surroundings of the pad electrode.

In an embodiment, a diameter of the nano-conductive particle may be greater than a thickness of the dielectric layer.

In an embodiment, the nano-conductive particles may include one of chromium and molybdenum.

### BRIEF DESCRIPTION OF DRAWINGS

FIG. 1 illustrates an assembled perspective view of an electronic apparatus, according to an embodiment.

FIG. 2 illustrates an exploded perspective view of the electronic apparatus depicted in FIG. 1, according to an embodiment.

FIG. 3 illustrates a cross-sectional view of the display module depicted in FIG. 2, according to an embodiment.

FIG. 4 illustrates a plan view showing the display panel depicted in FIG. 3, according to an embodiment.

FIG. 5 illustrates a plan view showing the input sensing unit depicted in FIG. 4, according to an embodiment.

FIG. 6 illustrates a perspective view showing a data driver and the display panel depicted in FIG. 4, according to an embodiment.

FIG. 7 illustrates a plan view showing a display panel, according to an embodiment.

FIG. 8 illustrates a plan view showing the first pad electrode depicted in FIG. 6, according to an embodiment.

FIG. 9 illustrates a cross-sectional view showing a display module, according to an embodiment.

FIG. 10 illustrates a cross-sectional view showing a bonding between a first pad electrode and the data driver depicted in FIG. 6, according to an embodiment.

FIG. 11 illustrates a cross-sectional view showing a first pad electrode and a data driver, of a comparative example, according to an embodiment.

FIG. 12 illustrates a graph showing electric connection properties between a data driver and a display panel, according to an embodiment.

FIG. 13A illustrates a cross-sectional view showing a first adhesive layer, according to an embodiment.

FIG. 13B illustrates a cross-sectional view showing a first adhesive layer, according to an embodiment.

### DETAILED DESCRIPTION

The advantages and features of the present invention will be apparent from the following exemplary embodiments that will be described below in detail with reference to the accompanying drawings. It should be noted, however, that the invention is not limited to the following exemplary embodiments, and may be implemented in various forms. Rather, the exemplary embodiments are provided only to disclose the present invention and let those skilled in the art fully know the scope of the invention. Like reference numerals refer to like elements throughout the specification.

It will be understood that when an element or layer is referred to as being “on” another element or layer, it can be directly on the other element or layer, or intervening elements or layers may also be present. In contrast, when an element is referred to as being “directly on” or “immediately on” another element, there are no intervening elements or layers. The term “and/or” includes any and all combinations or one or more of the associated listed items.

In this description, spatially relative terms such as “below”, “beneath”, “lower”, “above”, or “upper” may be used to easily describe one element or component's relationship to another element or component as illustrated in figures. It will be understood that spatially relative terms are intended to encompass different directions of devices when they are used or operated in addition to directions depicted in figures. Like reference numerals refer to like elements throughout the specification.

It will be understood that, although the terms first, second, etc. may be used herein to describe various elements, these elements should not be limited by these terms. These terms are only used to distinguish one device, element, or section from another device, element, or section. Thus, a first element, a first component, or a first section discussed below could be termed a second element, a second component, or a second section without departing from the technical idea of the present invention.

Embodiments herein will be described with reference to plan and cross-sectional views that are idealized schematic illustrations of the present invention. Accordingly, variations from the shapes of the illustrations as a result of manufacturing techniques and/or tolerances are to be expected. Thus, exemplary embodiments should not be construed as limited to the shapes of regions illustrated herein but are to include deviations in shapes that result from manufacturing process. Accordingly, regions exemplarily illustrated in the drawings have general properties, and shapes of regions exemplarily illustrated in the drawings are used to exemplarily disclose specific shapes but not limited to the scope of the present invention.

It will be understood that the terms “include” and/or “have”, when used in this specification, specify the presence of stated features, integers, steps, operations, elements, components and/or groups thereof, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, it will be discussed in detail preferable embodiments of the present invention in conjunction with the accompanying drawings.

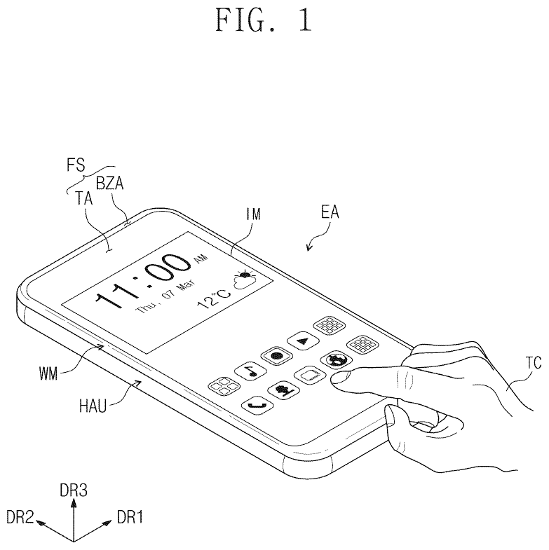

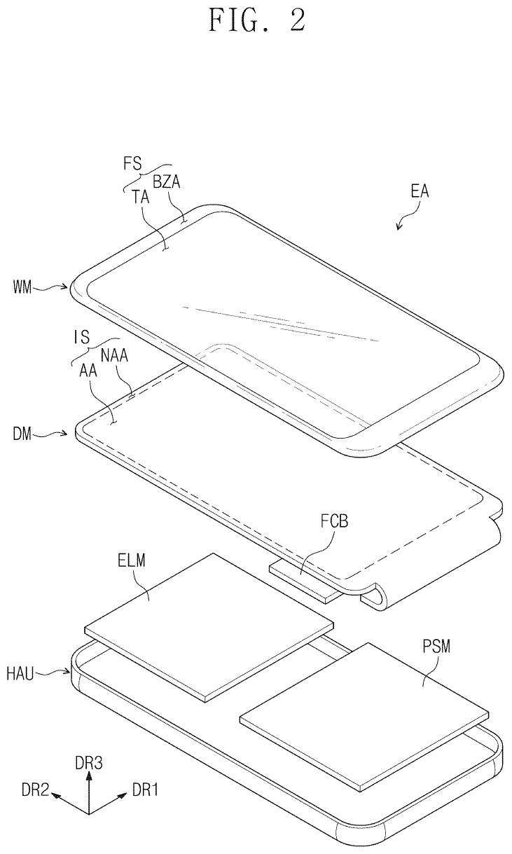

FIG. 1 illustrates an assembled perspective view of an electronic apparatus, according to an embodiment. FIG. 2 illustrates an exploded perspective view showing the electronic apparatus depicted in FIG. 1, according to an embodiment.

In an embodiment and referring to FIG. 1, an electronic apparatus EA may be a device that is activated with electrical signals to display an image IM and to detect an external input TC. For example, the electronic apparatus EA may include a device such as a monitor, a mobile phone, a tablet computer, a navigation system, and a game console. However, the described embodiments of the electronic apparatus EA are merely exemplary and are not limited to a specific embodiment. In the present embodiment, a mobile phone is exemplarily illustrated as the electronic apparatus EA.

In an embodiment, when viewed on a plane, the electronic apparatus EA may have a rectangular shape having short sides that extend in a first direction DR1 and long sides that extend in a second direction DR2 intersecting the first direction DR1. The present invention, however, is not limited thereto, and the electronic apparatus EA may have a circular shape, a polygonal shape, or any other suitable shapes when viewed on a plane.

In an embodiment, a third direction DR3 may indicate a direction perpendicular to a plane defined by the first direction DR1 and the second direction DR2. A front surface (or top surface) and a rear surface (or bottom surface) of each of components included in the electronic apparatus EA may be opposite to each other in the third direction DR3, and a normal direction to each of the front and rear surfaces may be parallel to the third direction DR3. An interval between the front and rear surfaces defined along the third direction DR3 may correspond to a thickness of the component.

In this disclosure, the phrase “when viewed on a plane” may be defined to refer to a state when viewed in the third direction DR3. In this disclosure, the expression “when viewed on a cross-section” may be defined to refer to a state when viewed in the first direction DR1 or the second direction DR2. Directions indicated by the first, second, and third directions DR1, DR2, and DR3 are relative concepts and may denote other directions.

In an embodiment, the electronic apparatus EA may be rigid or flexible. The term “flexible” may indicate the meaning of “being capable of being flexed”, and may include not only “being capable of completely folded” but also “being capable of bent to a certain degree of several nanometers.” For example, the flexible electronic apparatus EA may include a curved electronic device, a rollable electronic device, or a foldable electronic device.

In an embodiment, the electronic apparatus EA may display an image IM on a display surface FS which is directed parallel to each of the first direction DR1 and the second direction DR2. The image IM may include not only dynamic images but also static images. FIG. 1 depicts a clock widget and a plurality of icons as examples of the image IM.

In an embodiment, the display surface FS of the electronic apparatus EA may include only a flat surface or may further include a curved surface bended from at least one side of the flat surface. The display surface FS may correspond to a front surface of the electronic apparatus EA. In addition, a front surface FS of a window WM will be allocated the same reference numeral or symbol.

In an embodiment, the electronic apparatus EA may detect an external input TC that is externally applied thereto. The external input TC may include force, pressure, temperature, light, or any other various inputs. In the present embodiment, the external input TC is illustrated as a user's hand applied to a front surface of the electronic apparatus EA. However, this is exemplarily illustrated, and the external input TC may include an input, such as contact with a pen or hovering, applied in proximity to the electronic apparatus EA.

In an embodiment, the electronic apparatus EA may detect a user's input through the display surface FS defined on the front surface thereof, and may react in response to the detected input signal. In an embodiment, the detection of the external input TC, of the electronic apparatus EA, is not limited to the front surface of the electronic apparatus EA, and may be changed depending on design of the electronic apparatus EA. For example, the electronic apparatus EA may detect a user's input applied to a lateral or rear surface of the electronic apparatus EA.

In an embodiment and referring to FIGS. 1 and 2, the electronic apparatus EA may include a window WM, a display module DM, an electronic module ELM, a power module PSM, and a housing HAU. The housing HAU and the window WM may be coupled to constitute an appearance of the electronic apparatus EA.

In an embodiment, the window WM may be disposed on the display module DM. The window WM may cover a front surface IS of the display module DM, and may protect the display module DM against external impact and scratches. The window WM may be coupled through an adhesive layer to the display module DM.

In an embodiment, the window WM may include an optically transparent dielectric material. For example, the window WM may include glass or synthetic resin as a base film. The window WM may have a multi-layered or single-layered structure. For example, the multi-layered window WM may include either synthetic resin films combined through an adhesive or a glass film and a synthetic resin film that are combined through an adhesive. The window WM may further include a functional layer, such as an anti-fingerprint layer, a phase control layer, or a hard coating layer, disposed on a transparent base film.

In an embodiment, the front surface FS of the window WM may correspond to the front surface of the electronic apparatus EA. The front surface FS of the window WM may include a transmission region TA and a bezel region BZA.

In an embodiment, the transmission region TA may be an optically transparent area. The transmission region TA may transmit the image IM provided from the display module DM. In an embodiment, although the transmission region TA is illustrated to have a tetragonal shape, the present invention is not limited thereto and the transmission region TA may have any other various shapes.

In an embodiment, a bezel region BZA may be an area whose optical transmittance is relatively less than that of the transmission region TA. The bezel region BZA may correspond to an area printed with a material having a certain color. The bezel region BZA may suppress optical transmission to prevent the display module DM from being externally visible at its component that is disposed to overlap the bezel region BZA.

In an embodiment, the bezel region BZA may be disposed adjacent to the transmission region TA. The bezel region BZA may substantially define a shape of the transmission region TA. For example, the bezel region BZA may reside outside and surround the transmission region TA. This, however, is illustrated as an example, and the bezel region BZA may be adjacent to only one side of the transmission region TA or may be disposed not on the front surface of the electronic apparatus EA but on a lateral surface of the electronic apparatus EA. In another embodiment, the bezel region BZA may be omitted.

In an embodiment, the display module DM may be disposed between the window WM and the housing HAU. The display module DM may display the image IM and detect the external input TC. The image IM may be displayed on the front surface IS of the display module DM. The front surface IS of the display module DM may include an active region AA and a peripheral region NAA.

In an embodiment, the active region AA may be an area activated with an electrical signal. For example, the active region AA may be an area that displays the image IM and also detects the external input TC. The active region AA may overlap at least a portion of the transmission region TA. Therefore, a user may recognize the image IM through the transmission region TA or may provide the external input TC through the transmission region TA. This, however, is merely illustrated by way of example. The active region AA may be configured such that a region to display the image IM is separated from a region to detect the external input TC, but the present invention is not limited thereto.

In an embodiment, the peripheral region NAA may be disposed adjacent to the active region AA. For example, the peripheral region NAA may surround the active region AA. The peripheral region NAA may include a driver line or a driver circuit for driving the active region AA. The peripheral region NAA may overlap at least a portion of the bezel region BZA, and the bezel region BZA may prevent components of the peripheral region NAA from being externally visible.

In an embodiment, the display module DM may include a display panel and an input sensing unit. The display panel may display the image IM, and the input sensing unit may detect the external input TC. A detailed description thereof will be further discussed below.

In an embodiment, a portion of the display module DM may be bendable about a bending axis that extends in the first direction DR1. For example, the portion of the display module DM may be bent toward a rear surface of the display module DM that corresponds to the active region AA. The bent portion of the display module DM may be connected to a flexible circuit board FCB, and thus when viewed in plan, the flexible circuit board FCB may overlap the display module DM.

In an embodiment, the flexible circuit board FCB may be electrically connected to one side of the display module DM. The flexible circuit board FCB may generate an electrical signal provided to the display module DM or may receive a single generated from the display module DM to calculate an outcome value including information of sensing magnitude or position of the external input TC.

In an embodiment, the power module PSM may supply a power required for overall operation of the electronic apparatus EA. For example, the power module PSM may include an ordinary battery module.

In an embodiment, the electronic module ELM may include various functional modules that operate the electronic apparatus EA. For example, the electronic module ELM may include a control module, a wireless communication module, an image input module, a sound input module, a sound output module, a memory, an optical module, and an external interface module. The electronic module ELM may include a main circuit board, and the modules of the electronic module ELM may be mounted on the main circuit board or may be electrically connected through a discrete circuit board to the main circuit board.

In an embodiment, the control module of the electronic module ELM may control an overall operation of the electronic apparatus EA. For example, in response to a user's input, the control module may activate or inactivate the display module DM. The control module may include at least one microprocessor. The optical module of the electronic module ELM may include a camera module, a proximity sensor, a biometric sensor that detects a user's body part (e.g., fingerprint, iris, or face), or a light output lamp.

In an embodiment, the housing HAU may be combined with the window WM to provide an internal space that accommodates the display module DM, the electronic module ELM, the power module PSM, and the flexible circuit board FCB. The housing HAU may include a material whose rigidity is relatively high. For example, the housing HAU may include one selected from glass, plastic, and metal, or may include a plurality of frames and/or plates each including any combination of glass, plastic, and metal. The housing HAU may absorb externally applied impact or prevent externally introduced foreign substances/moisture to protect components of the electronic apparatus EA accommodated in the housing HAU.

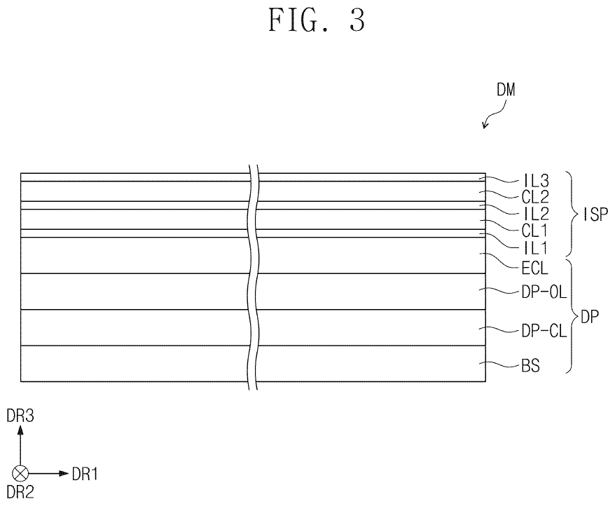

FIG. 3 illustrates a cross-sectional view showing the display module depicted in FIG. 2, according to an embodiment.

In an embodiment and referring to FIG. 3, the display module DM may include a display panel DP and an input sensing unit ISP. The input sensing unit ISP may be disposed on the display panel DP. For example, the input sensing unit ISP may be directly disposed on the display panel DP. In an embodiment, the phrase “the input sensing unit ISP is directly disposed on the display panel DP” may mean that the input sensing unit ISP is formed by a series of processes on the display panel DP, and the input sensing unit ISP and the display panel DP are combined without a discrete adhesive layer. For example, components of the input sensing unit ISP may be formed on a base surface provided from the display panel DP.

In an embodiment, the display panel DP may display an image in accordance with electrical signals. The display panel DP, according to an embodiment, may be an emissive display panel, but the invention is not particularly limited thereto. For example, the display panel DP may be an organic light-emitting display panel, an inorganic light-emitting display panel or a quantum-dot light-emitting display panel. An emission layer of the organic light-emitting display panel may include an organic light-emitting material, and an emission layer of the inorganic light-emitting display panel may include an inorganic light-emitting material. An emission layer of the quantum-dot light-emitting display panel may include a quantum-dot or a quantum-rod. The following will describe an example in which an organic light-emitting display panel is used as the display panel DP.

In an embodiment, the display panel DP may include a base substrate BS, a circuit layer DP-CL, a display element layer DP-OL, and an encapsulation layer ECL that are sequentially stacked along the third direction DR3 or along a direction directed from lower to upper portions of the display panel DP.

In an embodiment, the base substrate BS may be a rigid substrate or a flexible substrate that can be bendable, foldable, or rollable. For example, the base substrate BS may be a glass substrate, a metal substrate, or a polymer substrate. The base substrate BS may provide a base surface on which the circuit layer DP-CL is disposed.

In an embodiment, the base substrate BS may include an inorganic layer, an organic layer, or a composite material layer. The base substrate BS may have a single-layered or multi-layered structure. For example, the base substrate BS having a multi-layered structure may include synthetic resin layers and a multi-layered or single-layered inorganic layer disposed between the synthetic resin layers. The synthetic resin layer may include at least one selected from an acryl-based resin, a methacrylic-based resin, polyisoprene, a vinyl-based resin, an epoxy-based resin, a urethane-based resin, a cellulose-based resin, a siloxane-based resin, a polyamide-based resin, and a perylene-based resin, and the material of the synthetic resin layer is not limited thereto.

In an embodiment, the circuit layer DP-CL may be disposed on the base substrate BS. The circuit layer DP-CL may include at least one dielectric layer, at least one semiconductor pattern, and at least one conductive pattern. The dielectric layer, the semiconductor pattern, and the conductive pattern included in the circuit layer DP-CL may form pads, signal lines, and driving elements such as transistors.

In an embodiment, the display element layer DP-OL may be disposed on the circuit layer DP-CL. The display element layer DP-OL may include light-emitting elements each of which emits light. For example, the light-emitting elements may include an organic light-emitting element, an inorganic light-emitting element, micro-LED, or a nano-LED. The light-emitting elements of the display element layer DP-OL may be electrically connected to driving elements of the circuit layer DP-CL to emit light in accordance with electrical signals provided from the driving elements.

In an embodiment, the encapsulation layer ECL may be disposed on the display element layer DP-OL to encapsulate the light-emitting elements. The encapsulation layer ECL may include at least one film for increasing optical efficiency of the display element layer DP-OL or protecting the display element layer DP-OL. In an embodiment, the encapsulation layer ECL may include at least one selected from an inorganic layer and an organic layer. The inorganic layer of the encapsulation layer ECL may protect the light-emitting elements from moisture/oxygen. The organic layer of the encapsulation layer ECL may protect the light-emitting elements from foreign substances such as dust particles.

In an embodiment, the input sensing unit ISP may detect an external input to provide information of the external input so as to allow the display panel DP to display an image that corresponds to the external input. The input sensing unit ISP may be driven by a capacitance type, a resistive layer type, an infrared type, a sonic wave type, a pressure type, or any other suitable types, and the driving type of the input sensing unit ISP is not limited to a certain one as long as the input sensing unit ISP can detect an external input. In an embodiment, it is explained that the input sensing unit ISP is driven by a capacitance type.

In an embodiment, the input sensing unit ISP may include a base layer IL1, a first sensing conductive layer CL1, a first sensing dielectric layer IL2, a second sensing conductive layer CL2, and a second sensing dielectric layer IL3. The base layer IL1 of the input sensing unit ISP may be in contact with the encapsulation layer ECL. The invention, however, is not limited thereto, and at least one selected from the base layer IL1 and the second sensing dielectric layer IL3 may be omitted.

In an embodiment, each of the first and second sensing conductive layers CL1 and CL2 may have a single-layered or multi-layered structure. A conductive layer of the multi-layered structure may include at least two selected from transparent conductive layers and metal layers. The conductive layer of the multi-layered structure may include metal layers having different metals from each other. The transparent conductive layer may include at least one selected from indium tin oxide (ITO), indium zinc oxide (IZO), zinc oxide (ZnO), indium tin zinc oxide (ITZO), PEDOT(poly(3,4-ethylenedioxythiophene)), metal nano-wires, and graphene. The metal layer may include at least one selected from molybdenum, silver, titanium, copper, aluminum, and any alloy thereof. For example, each of the first and second sensing conductive layers CL1 and CL2 may have either a bi-layered structure, such as a bi-layered structure of ITO/copper, or a tri-layered structure of titanium/aluminum/titanium.

In an embodiment, each of the first and second sensing conductive layers CL1 and CL2 may include sensing conductive patterns. The sensing conductive patterns of the first and second sensing conductive layers CL1 and CL2 may form sensing electrodes that constitute the input sensing unit ISP and sensing lines connected to the sensing electrodes.

In an embodiment, each of the base layer IL1, the first sensing dielectric layer IL2, and the second sensing dielectric layer IL3 may include at least one selected from an inorganic layer and an organic layer. For example, in an embodiment, the inorganic layer may include at least one selected from aluminum oxide, titanium oxide, silicon oxide, silicon oxynitride, zirconium oxide, and hafnium oxide, and the organic layer may include at least one selected from an acryl-based resin, a methacrylic-based resin, polyisoprene, a vinyl-based resin, an epoxy-based resin, a urethane-based resin, a cellulose-based resin, a siloxane-based resin, a polyamide-based resin, and a perylene-based resin. However, the material of the inorganic layer and the organic layer is not limited to the example. The base layer IL1 may include an inorganic layer and each of the first and second sensing dielectric layers IL2 and IL3 may include an organic layer, but the invention is not limited thereto.

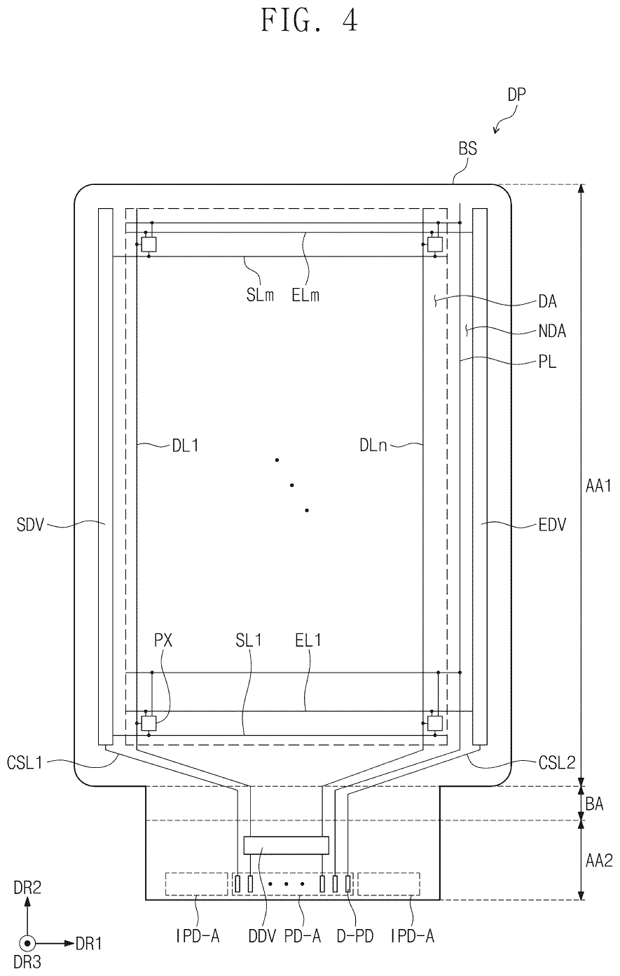

FIG. 4 illustrates a plan view showing the display panel depicted in FIG. 3, according to an embodiment.

In an embodiment and referring to FIG. 4, the display panel DP may include a base substrate BS, pixels PX, signal lines SL1 to SLm, DL1 to DLn, EL1 to Elm, CSL1, CSL2, and PL electrically connected to the pixels PX, a scan driver SDV, an emission driver EDV, a data driver DDV, and display pads D-PD.

In an embodiment, the base substrate BS may provide a base surface on which are disposed electrical elements and lines of the display panel DP. The base substrate BS may include a first base region AA1, a second base region AA2, and a bending region BA that are distinguished from each other in the second direction DR2. The bending region BA may extend in the second direction DR2 from the first base region AA1. The second base region AA2 may extend in the second direction DR2 from the bending region BA. Therefore, the first base region AA1 and the second base region AA2 may be spaced apart from each other across the bending region BA.

In an embodiment, the first base region AA1 may include a display region DA. The display region DA may be an area where light-emitting elements of the pixels PX are disposed. Thus, the pixels PX may display an image through the display region DA. The display region DA may correspond to the active region (see AA of FIG. 2) of the display module (see DM of FIG. 2) and may overlap the transmission region (see TA of FIG. 2) of the window (see WM of FIG. 2).

In an embodiment, a non-display region NDA may be defined to refer to the second base region AA2, the bending region BA, and the first base region AA1 except the display region DA. The non-display region NDA may be an area which is disposed adjacent to the display region DA and on which no image is displayed. The non-display region NDA may surround the display region DA. The non-display region NDA may include the scan driver SDV, the emission driver EDV, and the data driver DDV for driving the pixels PX, and may also include the display pads D-PD electrically connected to the signal lines SL1 to SLm, DL1 to DLn, EL1 to ELm, CSL1, CSL2, and PL. The signal lines SL1 to SLm, DL1 to DLn, EL1 to ELm, CSL1, CSL2, and PL electrically connected to the pixels PX may be disposed extending on the non-display region NDA.

In an embodiment, the bending region BA may be an area that bends about a bending axis that extends in the first direction DR1. For example, the bending region BA may band toward a rear surface of the display panel DP that corresponds to the first base region AA1. When the bending region BA bends, the second base region AA2 extending from one side of the bending region BA may overlap the first base region AA1 when viewed in plan. For example, the second base region AA2 may be disposed on the rear surface of the display panel DP that corresponds to the first base region AA1.

In an embodiment, when viewed in the first direction DR1, a width of each of the bending region BA and the second base region AA2 may be less than a width of the first base region AA1. When viewed in a direction parallel to the bending axis, the bending region BA may have a width less than that of the first base region AA1, and thus the bending region BA may easily band. This, however, is illustrated by way of example, and when viewed in the first direction DR1, at least one of the widths of the bending region BA and the second base region AA2 may be the same as the width of the first base region AA1, but the invention is not limited thereto.

In an embodiment, when the bending region BA bends, the second base region AA2 may be planarly positioned below the first base region AA1. The second base region AA2 may be an area where are disposed the data driver DDV and ones of the signal lines SL1 to SLm, DL1 to DLn, EL1 to ELm, CSL1, CSL2, and PL that extend through the bending region BA toward the display pads D-PD.

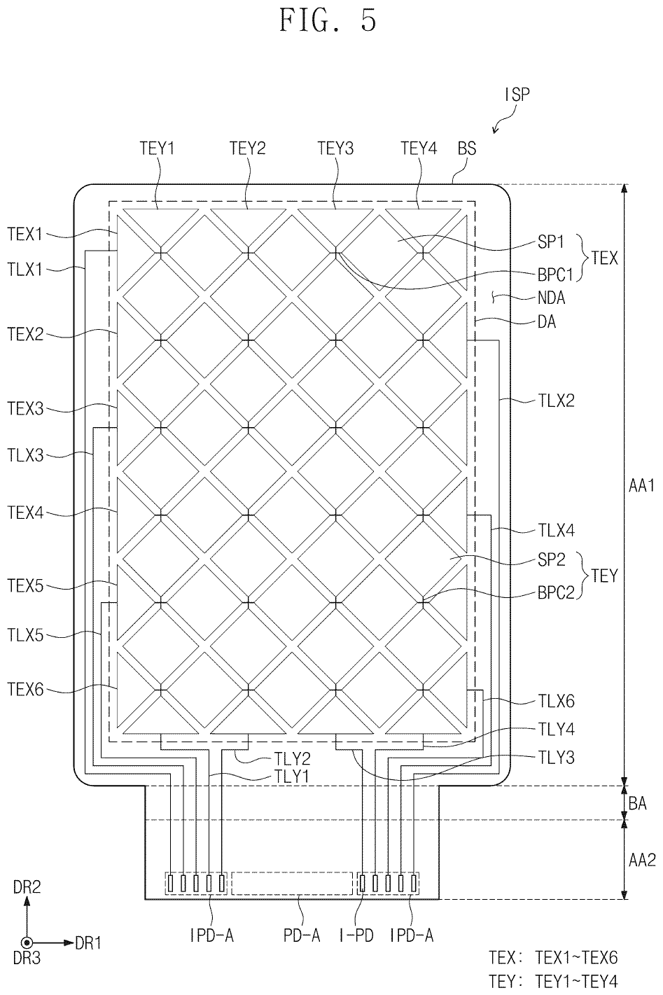

In an embodiment, a display pad region PD-A may be defined to refer to an area where the display pads D-PD are disposed, and a sensing pad region IPD-A may be defined to refer to an area where are disposed sensing pads (see I-PD of FIG. 5) which will be discussed below. FIG. 4 depicts by way of example that the display pad region PD-A and the sensing pad region IPD-A are distinguished from each other in the first direction DR1. For example, the sensing pad region IPD-A may be provided adjacent to opposite sides in the first direction DR1 of the second base region AA2, and the display pad region PD-A may be provided on a central portion of the second base region AA2. The invention, however, is not limited thereto, and the arrangement positions of the display pads D-PD and sensing pads (see I-PD of FIG. 5) may be variously changed.

In an embodiment, the flexible circuit board (see FCB of FIG. 2) may be disposed on the second base region AA2 on which the display pads D-PD and the sensing pads (see I-PD of FIG. 5) are located and may be electrically connected to the display pads D-PD and the sensing pads (see I-PD of FIG. 5). The flexible circuit board (see FCB of FIG. 2) disposed adjacent to a bottom end of the second base region AA2 may be positioned on the rear surface of the display panel DP due to the bending of the bending region BA. On the front surface of the electronic apparatus EA, the second base region AA2 and the flexible circuit board (see FCB of FIG. 2) may be positioned below the first base region AA1, and thus there may be a reduction in bezel area of the electronic apparatus (see EA of FIG. 2).

In an embodiment, each of the pixels PX may include a pixel driving circuit including transistors (e.g., a switching transistor and a driving transistor) and at least one capacitor and may also include a light-emitting element electrically connected to the pixel driving circuit. The pixels PX may generate light in response to an electrical signal applied to each of the pixels PX, and may display an image through the display region DA. In an embodiment, a portion of the pixels PX may include a transistor disposed on the non-display region NDA, but the invention is not limited thereto.

In an embodiment, the scan driver SDV and the emission driver EDV may be disposed on the non-display region NDA that corresponds to the first base region AA1. The data driver DDV may be disposed on the non-display region NDA that corresponds to the second base region AA2. In an embodiment, the data driver DDV may be provided in the form of an integrated circuit chip mounted on the non-display region NDA of the display panel DP. The invention, however, is not limited thereto, and the data driver DDV may be mounted on the flexible circuit board (see FCB of FIG. 2).

In an embodiment, the signal lines SL1 to SLm, DL1 to DLn, EL1 to ELm, CSL1, CSL2, and PL may include scan lines SL1 to SLm, data lines DL1 to DLn, emission lines EL1 to Elm, first and second control lines CSL1 and CSL2, respectively, and a power line PL. The subscripts “m” and “n” are natural numbers.

In an embodiment, the data lines DL1 to DLn may be insulated from and intersect the scan lines SL1 to SLm and the emission lines EL1 to ELm. For example, the scan lines SL1 to SLm may extend in the first direction DR1 to come into electrical connection with the scan driver SDV. The data lines DL1 to DLn may extend in the second direction DR2 to come into electrical connection with the data driver DDV. The emission lines EL1 to ELm may extend in the first direction DR1 to come into connection with the emission driver EDV.

In an embodiment, the power line PL may include segments that extend in the first direction DR1 and segments that extend in the second direction DR2. The segment of the power line PL extending in the first direction DR1 and the segment of the power line PL extending in the second direction DR2 may be located at different layers (or levels) or at the same layer (or level) to constitute a single unitary piece. The segments of the power line PL extending in the first direction DR1 may be electrically connected to the pixels PX and the segments extending in the second direction DR2. The segments of the power line PL extending in the second direction DR2 may be disposed on the non-display region NDA, and may extend from the first base region AA1 through the bending region BA and the second base region AA2, to come into electrical connection with the display pads D-PD, thereby coming electrical connection with the display pads D-PD. The power line PL may provide the pixels PX with a first voltage.

In an embodiment, the first control line CSL1 may be electrically connected to the scan driver SDV and may extend through the bending region BA toward the bottom end of the second base region AA2. The second control line CSL2 may be electrically connected to the emission driver EDV and may extend through the bending region BA toward the bottom end of the second base region AA2.

In an embodiment, the display pads D-PD may be disposed adjacent to the bottom end of the second base region AA2. On the second base region AA2, the display pads D-PD may be disposed closer the data driver DDV to a bottom end of the base substrate BS. The display pads D-PD may be disposed to be spaced apart from each other in the first direction DR1. Each of the power line PL, the first control line CSL1, and the second control line CSL2 may be electrically connected to a corresponding one of the display pads D-PD. The data lines DL1 to DLn may be electrically connected through the data driver DDV to a corresponding one of the display pads D-PD.

In an embodiment, the display pads D-PD may be electrically connected through an anisotropic conductive adhesive layer to the flexible circuit board (see FCB of FIG. 2), and electrical signals provided from the flexible circuit board (see FCB of FIG. 2) may be transmitted through the display pads D-PD to the display panel DP. However, the connection type between the display pads D-PD and the flexible circuit board (see FCB of FIG. 2) is not limited thereto.

In an embodiment, the scan driver SDV may generate scan signals in response to a scan control signal. The scan signals may be applied through the scan lines SL1 to SLm to the pixels PX. In response to a data control signal, the data driver DDV may generate data voltages that correspond to image signals. The data voltages may be applied through the data lines DL1 to DLn to the pixels PX. In response to an emission control signal, the emission driver EDV may generate emission signals. The emission signals may be applied through the emission lines EL1 to ELm to the pixels PX.

In an embodiment, in response to the scan signals, the data voltages may be provided to the pixels PX. In response to the emission signals, the pixels PX may emit light whose brightness corresponds to the data voltages, thereby generating images. The emission signals may control light emission timing of the pixels PX.

FIG. 5 illustrates a plan view of the input sensing unit depicted in FIG. 4, according to an embodiment.

For convenience of description, FIG. 5 simply depicts components of the input sensing unit ISP disposed on the base substrate BS, according to an embodiment.

In an embodiment, the input sensing unit ISP may be driven by a mutual capacitance type. Referring to FIG. 5, the input sensing unit ISP may include first sensing electrodes TEX (TEX1 to TEX6), second sensing electrodes TEY (TEY1 to TEY4), first sensing lines TLX1 to TLX6, second sensing lines TLY1 to TLY4, and sensing pads I-PD. The invention, however, is not limited thereto, and the input sensing unit ISP may be driven by a self-capacitance type.

In an embodiment, the first sensing electrodes TEX may each extend along the first direction DR1, and may be arranged along the second direction DR2. FIG. 5 depicts by way of example six first sensing electrodes TEX1 to TEX6. However, there is no limitation imposed on the number of the first sensing electrodes TEX that may be included in the input sensing unit ISP. One first sensing electrode TEX may include first sensing patterns SP1 arranged along the first direction DR1 and first connection patterns BPC1 that connect the first sensing patterns SP1 to each other.

In an embodiment, the second sensing electrodes TEY may each extend along the second direction DR2, and four second sensing electrodes TEY1 to TEY4 are illustrated by way of example. However, there is no limitation imposed on the number of the second sensing electrodes TEY that may be included in the input sensing unit ISP. One second sensing electrode TEY may include second sensing patterns SP2 arranged along the second direction DR2 and second connection patterns BPC2 that connect the second sensing patterns SP2 to each other.

In an embodiment, the first sensing electrodes TEX may be electrically insulated from the second sensing electrodes TEY. The input sensing unit ISP may detect an external input based on a variation in capacitance between the first sensing electrodes TEX and the second sensing electrodes TEY. The first sensing electrodes TEX and the second sensing electrodes TEY may be disposed on a region that corresponds to the display region DA of the base substrate BS. Therefore, the electronic apparatus (see EA of FIG. 1) may not only display an image through the display region DA, but may also detect an external input applied to the display region DA.

In an embodiment, the first sensing lines TLX1 to TLX6 may be disposed on the non-display region NDA to come into electrical connection with the first sensing electrodes TEX1 to TEX6, respectively. One or more of the first sensing lines TLX1 to TLX6 may be disposed on a left side of the non-display region NDA, and a remaining one or more of the first sensing lines TLX1 to TLX6 may be disposed on a right side of the non-display region NDA. For example, the first sensing lines TLX1, TLX3, and TLX5 connected to the first sensing electrodes TEX1, TEX3, and TEX5, respectively, disposed in odd-numbered rows may be connected to left sides of the first sensing electrodes TEX1, TEX3, and TEX5, respectively, and the first sensing lines TLX2, TLX4, and TLX6 connected to the first sensing electrodes TEX2, TEX4, and TEX6, respectively, disposed in even-numbered rows may be connected to right sides of the first sensing electrodes TEX2, TEX4, and TEX6, respectively. However, an arrangement of the first sensing lines TLX1 to TLX6 is not limited thereto, and all of the first sensing lines TLX1 to TLX6 may be disposed either on the left side of the non-display region NDA or on the right side of the non-display region NDA.

In an embodiment, each of the first sensing lines TLX1 to TLX6 may extend from the first base region AA1 through the bending region BA toward the second base region AA2. The first sensing lines TLX1 to TLX6 may be correspondingly electrically connected to the sensing pads I-PD disposed on the second base region AA2.

In an embodiment, the second sensing lines TLY1 to TLY4 may be disposed on the non-display region NDA to come into electrical connection with the second sensing electrodes TEY1 to TEY4, respectively. One or more of the second sensing lines TLY1 to TLY4 may be disposed on the left side of the non-display region NDA, and a remaining one or more of the second sensing lines TLY1 to TLY4 may be disposed on the right side of the non-display region NDA. For example, when viewed in the first direction DR1, second sensing lines TLY1 and TLY2 electrically connected to the second sensing electrodes TEY1 and TEY2, respectively, disposed on a left side among the second sensing electrodes TEY1 to TEY4 may be disposed adjacent to a left side of the first base region AA1, and the second sensing lines TLY3 and TLY4 electrically connected to the second sensing electrodes TEY3 and TEY4, respectively, disposed on a right side among the second sensing electrodes TEY1 to TEY4 may be disposed adjacent to a right side of the first base region AA1. However, an arrangement of the second sensing lines TLY1 to TLY4 is not limited thereto.

In an embodiment, each of the second sensing lines TLY1 to TLY4 may extend from a region disposed adjacent to the bottom end of the first base region AA1 through the bending region BA toward the second base region AA2. The second sensing lines TLY1 to TLY4 may be correspondingly electrically connected to the sensing pads I-PD disposed on the second base region AA2.

In an embodiment, when viewed in the first direction DR1, one or more of the sensing pads I-PD may be disposed adjacent to a left side of the second base region AA2, and a remaining one or more of the sensing pads I-PD may be disposed adjacent to a right side of the second base region AA2. For example, the sensing pads I-PD may be divided into two groups that are spaced apart from each other across the display pad region PD-A. However, an arrangement of the sensing pads I-PD is not limited thereto.

In an embodiment, the sensing pads I-PD may be located at the same layer as that of the display pads (see D-PD of FIG. 4). The sensing pads I-PD may be located at a different layer from that of the first and second sensing lines TLX1 to TLX6 and TLY1 to TLY4, respectively, to connect to each other through a contact hole. This, however, is not limited thereto, and the sensing pads I-PD may be located at a different layer from that of the display pads (see D-PD of FIG. 4). For example, the sensing pads I-PD may be formed into a single unitary piece located at the same layer as that of the first and second sensing lines TLX1 to TLX6 and TLY1 to TLY4, respectively.

In an embodiment, on a region that corresponds to the non-display region NDA of the base substrate BS, the first and second sensing lines TLX1 to TLX6 and TLY1 to TLY4, respectively, may be located higher than components of the display panel (see DP of FIG. 4). Therefore, on the bending region BA and the second base region AA2, the first and second sensing lines TLX1 to TLX6 and TLY1 to TLY4, respectively, may overlap components of the display panel (see DP of FIG. 4).

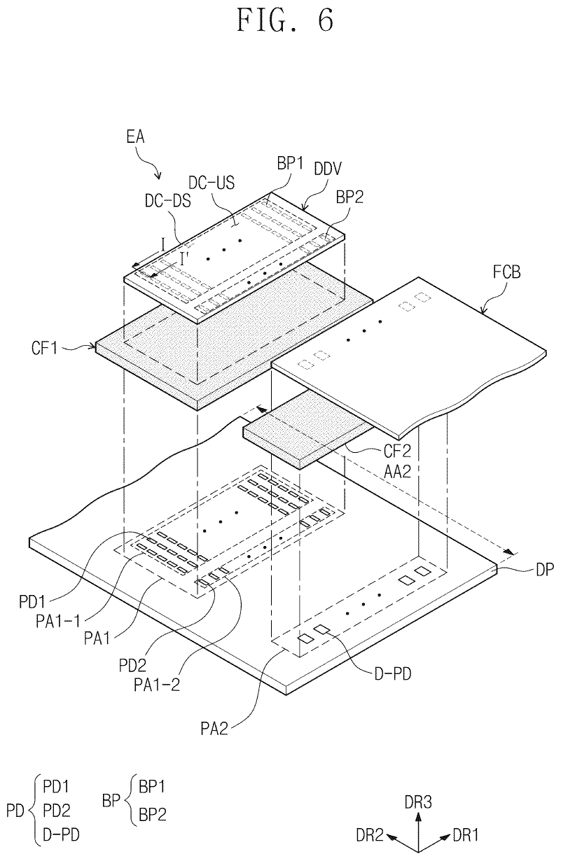

FIG. 6 illustrates a perspective view showing a data driver and the display panel depicted in FIG. 4, according to an embodiment.

In an embodiment, FIG. 6 simply depicts a partial area of the display panel DP disposed corresponding to the second base region AA2. In addition, the second base region AA2 may correspond to a partial area of the non-display region (see NDA of FIG. 4).

FIG. 6 depicts by way of example the data driver DDV separated from the display panel DP, according to an embodiment.

In an embodiment and referring to FIG. 6, the data driver DDV may be disposed on the display panel DP. The data driver DDV may have a top surface DC-US and a bottom surface DC-DS. The bottom surface DC-DS of the data driver DDV may be defined as a surface that faces the display panel DP.

In an embodiment, the data driver DDV may include bump electrodes BP. The bump electrodes BP may be disposed on the bottom surface DC-DS of the data driver DDV.

In an embodiment, the bump electrodes BP may include a plurality of first bump electrodes BP1 and a plurality of second bump electrodes BP2. The first bump electrodes BP1 may be spaced apart in the second direction DR2 from the second bump electrodes BP2. The first bump electrodes BP1 may be arranged in the first direction DR1. The second bump electrodes BP2 may be arranged in the first direction DR1. Although not shown, the first bump electrodes BP1 and the second bump electrodes BP2 may have their shapes that are outwardly exposed while protruding from the bottom surface DC-DS of the data driver DDV

In an embodiment, the display panel DP may include a plurality of pad electrodes PD. The plurality of pad electrodes PD may include first pad electrodes PD1, second pad electrodes PD2, and display pads D-PD. The first pad electrodes PD1, the second pad electrodes PD2, and the display pads D-PD may be pads disposed on a signal transfer path. The display pads D-PD may be panel input pads that receive signals from the flexible circuit board FCB.

In an embodiment and as illustrated in FIG. 6, a first pad region PA1 may be defined to refer to an area to which the data driver DDV is bonded, and a second pad region PA2 may be defined to refer to an area to which the flexible circuit board FCB is bonded.

In an embodiment, the first pad region PA1 may include a first sub-pad region PA1-1 and a second sub-pad region PA1-2. The first sub-pad region PA1-1 may be defined to refer to an area on where the first pad electrodes PD1 are disposed. The second sub-pad region PA1-2 may be defined to refer to an area where the second pad electrodes PD2 are disposed.

In an embodiment, the first pad electrodes PD1 may be arranged along the first direction DR1 and the second direction DR2 on the first sub-pad region PA1-1. A pad row may be defined to refer to the first pad electrodes PD1 arranged along the first direction DR1. FIG. 6 depicts by way of example that five pad rows are arranged along the second direction DR2. An arrangement of the first pad electrodes PD1 is not limited to a certain arrangement as long as at least two pad rows are arranged along the second direction DR2. The first pad electrodes PD1 may be input pads that are disposed corresponding to the first bump electrodes BP1 of the data driver DDV and receive signals from the data driver DDV.

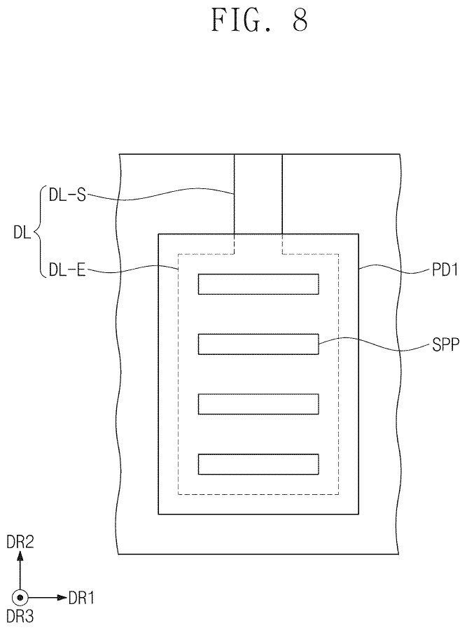

In an embodiment, although not shown, the first pad electrodes PD1 may be electrically connected through signal lines to the pixels (see PX of FIG. 4) of the display panel DP and may transmit and receive signals with the pixels (see PX of FIG. 4). This will be further discussed in detail in FIG. 8.

In an embodiment, the second pad electrodes PD2 may be arranged along the first direction DR1 on the second sub-pad region PA1-2. The second pad electrodes PD2 may be disposed in one pad row. However, an arrangement of the second pad electrodes PD2 is not limited thereto. The second pad electrodes PD2 may be output pads that are disposed corresponding to the second bump electrodes BP2 of the data driver DDV and output signals to the data driver DDV.

In an embodiment, although not shown, each of the second pad electrodes PD2 may be electrically connected through a signal line to a corresponding one of the display pads D-PD, and the display pad D-PD and the second pad electrodes PD2 that are electrically connected to each other may transmit and receive signals.

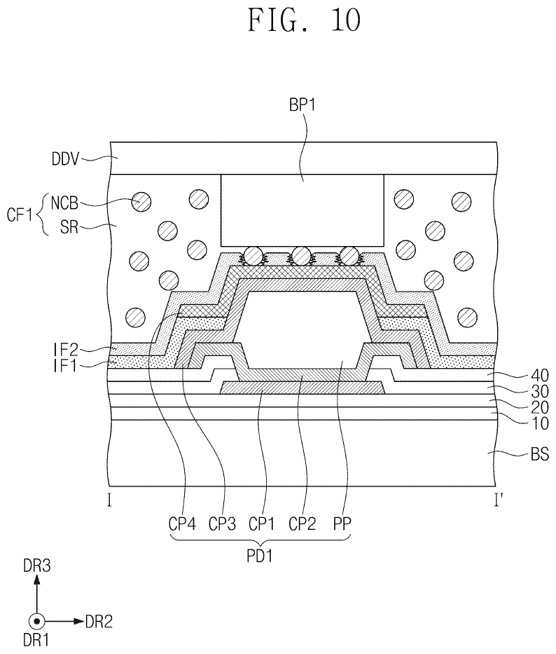

In an embodiment, the data driver DDV may be bonded through a first adhesive layer CF1 to the first pad region PA1, and the flexible circuit board FCB may be bonded through a second adhesive layer CF2 to the second pad region PA2. Each of the first and second adhesive layers CF1 and CF2, respectively, may be a non-conductive film. Although not shown, the first adhesive layer CF1 and the second adhesive layer CF2 may include nano-conductive particles. The nano-conductive particle will be discussed in detail in FIG. 10.

In an embodiment, the first bump electrodes BP1 may be electrically connected to the first pad electrodes PD1. The second bump electrodes BP2 may be electrically connected to the second pad electrodes PD2. An electrical connection between the first bump electrode BP1 and the first pad electrodes PD1 will be discussed in detail in FIG. 10, and an electrical connection between the second bump electrode BP2 and the second pad electrode PD2.

In an embodiment, although not shown, the data driver DDV may include an integrated circuit. The integrated circuit may be disposed on the bump electrodes BP. The integrated circuit may be connected to the bump electrodes BP. The data driver DDV may receive first signals from the outside through the second pad electrodes PD2 and the second bump electrodes BP2. Second signals generated based on signals may be provided from the data driver DDV through the first bump electrodes BP1 to the first pad electrodes PD1. The first signal may be an image signal that is an externally applied digital signal, and the second signal may be a data signal that is an analog signal. The data driver DDV may generate an analog voltage that corresponds to a grayscale value of an image signal. The data signal may be provided to the pixel PX through the data line DL depicted in FIG. 4.

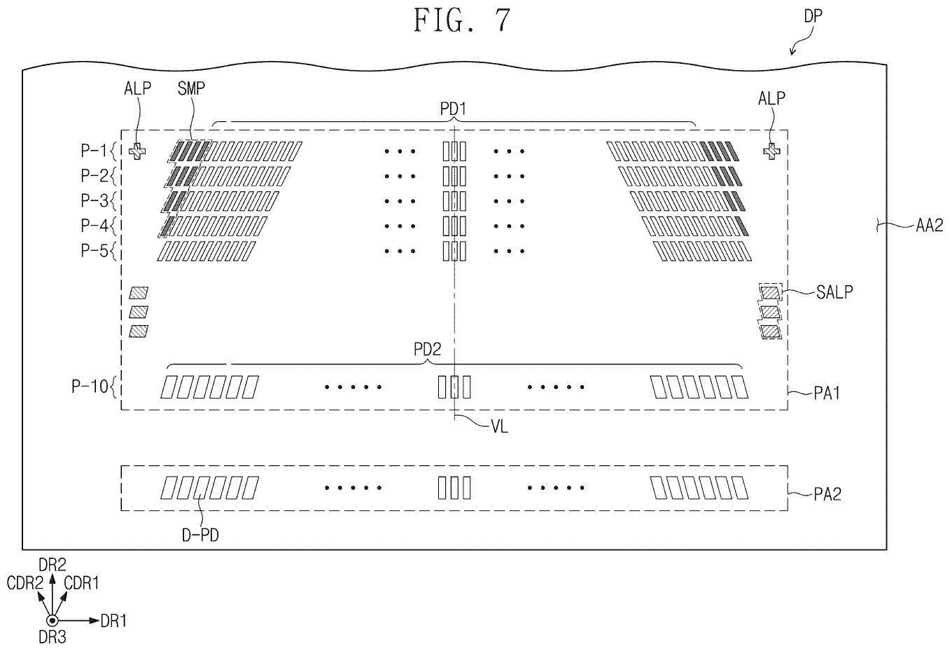

FIG. 7 illustrates a plan view showing a display panel, according to an embodiment.

In an embodiment, FIG. 7 is a plan view showing a portion of the display panel DP that corresponds to the second base region AA2 of FIG. 4. The description above will be applied to each component.

FIG. 7 show an enlarged illustration of the first and second pad regions PA1 and PA2, according to an embodiment.

In an embodiment and referring to FIG. 7, the first pad electrodes PD1 and the second pad electrodes PD2 may be disposed on the first pad region PA1. The first pad electrodes PD1 may be disposed in five pad rows P-1 to P-5 on a region disposed adjacent to an upper portion of the first pad region PA1. The five pad rows P-1 to P-5 may be defined as first to fifth input pad rows P-1 to P-5, respectively. The second pad electrodes PD2 may be disposed in one pad row P-10 on a region disposed adjacent to a lower portion of the first pad region PA1. The one pad row P-10 may be defined as a first output pad row P-10.

In an embodiment, the first pad electrodes PD1 may include first central pads disposed on a center in the first direction DR1 and may be arranged on a reference line VL. The first central pads may extend along the second direction DR2. The first pad electrodes PD1 disposed on left and right sides of the reference line VL may extend at a certain slope with respect to the reference line VL. The first pad electrodes PD1 disposed on the left side of the reference line VL may extend in a first diagonal direction CDR1. The first pad electrodes PD1 disposed on the left side may extend at an acute angle in a clockwise direction from the reference line VL. The first pad electrodes PD1 disposed on the right side of the reference line VL may extend in a second diagonal direction CDR2. The first pad electrodes PD1 disposed on the right side may extend at an acute angle in a counterclockwise direction from the reference line VL. The first diagonal direction CDR1 may be defined to indicate a direction that intersects the first direction DR1 and the second direction DR2. The second diagonal direction CDR2 may be defined to indicate a direction that intersects the first diagonal direction CDR1.

In an embodiment, the second pad electrodes PD2 may include a second central pad disposed on a center in the first direction DR1 may be arranged on the reference line VL. The second central pad may extend along the second direction DR2. The second pad electrodes PD2 disposed on left and right sides of the reference line VL may extend at a certain slope with respect to the reference line VL. The second pad electrodes PD2 disposed on the left side of the reference line VL may extend at an acute angle in a clockwise direction from the reference line VL, and the second pad electrodes PD2 disposed on the right side of the reference line VL may extend at an acute angle in a counterclockwise direction from the reference line VL.

In an embodiment, the display panel DP may further include dummy pads SMP. The dummy pads SMP may be disposed on the first pad region PA1. The dummy pads SMP may be electrically isolated pads and may be disposed to fill regions between the first pad electrodes PD1 and an edge of the second base region AA2.

In an embodiment, the dummy pads SMP may be disposed to be located more outside than the first pad electrodes PD1 disposed on outermost positions in at least one of the first to fifth input pad rows P-1 to P-5, respectively. The dummy pads SMP may be disposed adjacent to the left and right sides of the first pad region PA1. FIG. 7 depicts by way of example the dummy pads SMP disposed on outer sections of the first to fourth input pad rows P-1 to P-4, respectively, among the first to fifth input pad rows P-1 to P-5, respectively, but the arrangement of the dummy pads SMP are not limited thereto.

In an embodiment, the dummy pads SMP may extend in a direction parallel to the extending direction of the first pad electrodes PD1 disposed adjacent thereto. The dummy pads SMP adjacent to one pad row may be disposed side by side along the first direction DR1 with the first pad electrodes PD1 located in the one pad row.

In an embodiment, the display panel DP may further include an alignment pad ALP. The alignment pad ALP may be disposed adjacent to the first pad region PA1. The alignment pad ALP may be provided in plural, and the plurality of alignment pads ALP may be disposed adjacent to left and right corners of the first pad region PA1.

In an embodiment, the alignment pad ALP may be an identification mark or an alignment mark for aligning the data driver (see DDV of FIG. 6) with the first pad region PA1 of the display panel DP in a process where the data driver DDV is bonded to the first pad region PA1 of the display panel DP. FIG. 7 depicts by way of example that the alignment pad ALP has a cross shape, but the alignment pad ALP is not limited to any one shape and may have a circular shape, a polygonal shape, or any other suitable shapes as long as the alignment pad ALP can align the data driver DDV and the display panel DP with each other.

In an embodiment, the dummy pads SMP and the alignment pad ALP may be formed in the same process and may include the same material. In an embodiment, at least one of the dummy pads SMP and the alignment pad ALP may include the same material as that of the first pad electrodes PD1. At least one of the dummy pads SMP and the alignment pad ALP may be formed in the same process for forming the first pad electrodes PD1.

In an embodiment, the display panel DP may further include sub-alignment pads SALP. The sub-alignment pads SALP may be disposed on the first pad region PA1. One or more of the sub-alignment pads SALP may be disposed adjacent to a left side of the first pad region PA1, and another or more of the sub-alignment pads SALP may be disposed adjacent to a right side of the first pad region PA1.

In an embodiment, the sub-alignment pad SALP may be an identification mark or an alignment mark for aligning the data driver (see DDV of FIG. 6) with the display panel DP in a process where the data driver DDV is bonded to the first pad region PA1 of the display panel DP or inspecting whether the data driver DDV and the display panel DP are appropriately aligned with each other. FIG. 7 depicts by way of example that the sub-alignment pad SALP has a tetragonal shape, but the sub-alignment pad SALP is not limited to any one shape and may have a circular shape, a polygonal shape, or any other suitable shapes as long as it is possible to ascertain an alignment between the data driver DDV and the display panel DP.

FIG. 8 illustrates a plan view showing the first pad electrode depicted in FIG. 6, according to an embodiment.

In an embodiment, FIG. 8 depicts, by way of example, one of the first pad electrodes PD1 shown in FIG. 6. The invention, however, is not limited thereto, and the second pad electrodes (see PD2 of FIG. 7) and the display pads (see D-PD of FIG. 7) may also have the same structure as that of the first pad electrodes PD1.

FIG. 8 shows a plan view by way of example, according to an embodiment.

In an embodiment and referring to FIG. 8, the first pad electrodes PD1 may be electrically connected through signal lines to the pixels (see PX of FIG. 4) of the display panel DP and may transceive signals with the pixels (see PX of FIG. 4).

In an embodiment, the signal line may be a data line DL. The invention, however, is not limited thereto, and the signal line may be a different signal line other than the data line DL.

In an embodiment, when viewed in a plan view, the data line DL may include an end portion DL-E and a line portion DL-S having different widths in the first direction DR1. The width in the first direction DR1 of the end portion DL-E may be greater than the width in the first direction DR1 of the line portion DL-S. The invention, however, is not limited thereto, and the end portion DL-E and the line portion DL-S may have the same width.

In an embodiment, when viewed in a plan view, the first pad electrode PD1 may cover the data line DL. The first pad electrode PD1 may include a plurality of dielectric patterns SPP. The dielectric patterns SPP, when viewed in a plan view, may overlap the data line DL.

In an embodiment, when viewed in a plan view, the dielectric patterns SPP may be arranged in the second direction DR2. Although FIG. 8 depicts by way of example four dielectric patterns SPP, the invention is not limited thereto, and the first pad electrode PD1 may include one, two, three, or five or more dielectric patterns SPP.

In an embodiment, when viewed in a plan view, each of the dielectric patterns SPP may have a rectangular shape. For example, in an embodiment, about 5 micrometers may be given as a length in the first direction DR1 of the dielectric pattern SPP, and about 2 micrometers may be given as a length in the second direction DR2 of the dielectric pattern SPP. This, however, is merely exemplary, and the dielectric pattern SPP may have a circular shape, an oval shape, or any other suitable shapes. In addition, the dielectric pattern SPP may have their lengths in the first direction DR1 and the second direction DR2 that are changed differently from the example mentioned above.

In an embodiment, although not shown, the dielectric patterns SPP may protrude more than the surroundings of the dielectric patterns SPP on the first pad electrode PD1. The protrusion of the dielectric pattern SPP may cause a connection with the bump electrode BP of FIG. 6. This will be further discussed in detail in FIG. 10.

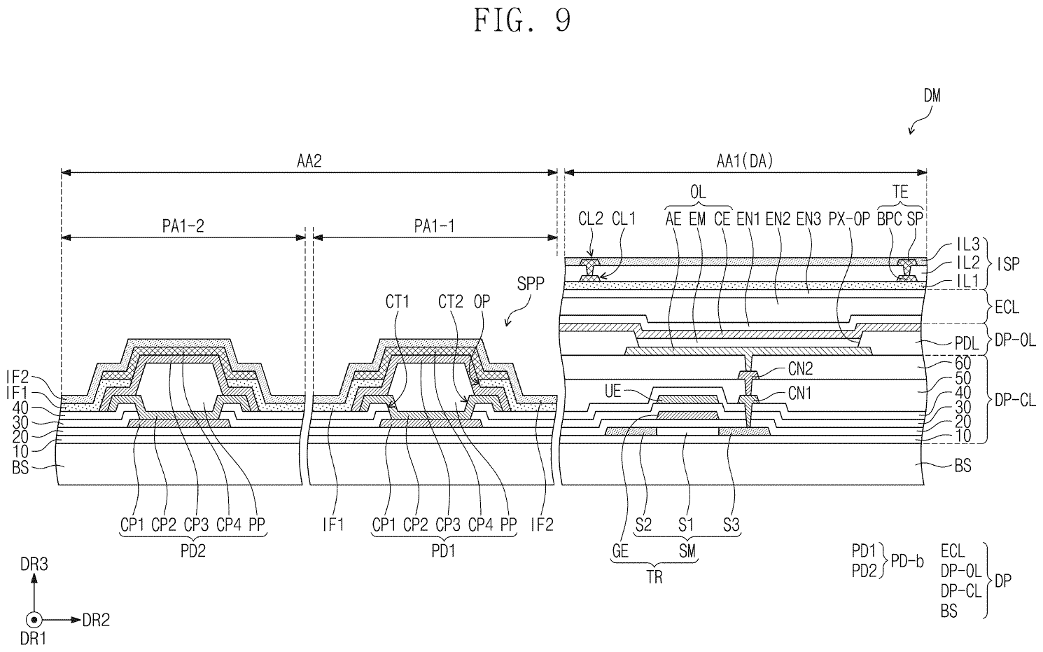

FIG. 9 illustrates a cross-sectional view showing a display module, according to an embodiment.

In an embodiment, FIG. 9 depicts, by way of example, a cross-section of the pixel (see PX of FIG. 4) disposed on the first base region AA1 and cross-sections of the first and second pad electrodes PD1 and PD2 disposed on the second base region AA2.

In an embodiment and referring to FIG. 9, the display module DM may include a display panel DP and an input sensing unit ISP disposed on the display panel DP.

In an embodiment, the display panel DP may include a base substrate BS, a circuit layer DP-CL, and an encapsulation layer ECL.

In an embodiment, the base substrate BS may have a dielectric layer and may provide a base surface on which components of the display module DM are disposed. The base substrate BS may have flexibility to bend. As discussed above, the base substrate BS may include a first base region AA1, a bending region (see BA of FIG. 4), and a second base region AA2, and the bending region (see BA of FIG. 4) of the base substrate BS may be bent with a certain curvature.

In an embodiment, the circuit layer DP-CL may include dielectric layers 10 to 60, a transistor TR of the pixel (see PX of FIG. 4), an upper electrode UE, and connection electrodes CN1 and CN2 that are disposed on the base substrate BS. The dielectric layers 10 to 60 may include first to sixth dielectric layers 10 to 60, respectively, that are sequentially stacked along a thickness direction on the base substrate BS. However, an embodiment of the dielectric layers 10 to 60 included in the circuit layer DP-CL is not limited thereto, and may be changed in accordance with a configuration and fabrication process of the circuit layer DP-CL.

In an embodiment, the first dielectric layer 10 may be disposed on the base substrate BS. The first dielectric layer 10 may be provided as a barrier layer and/or a buffer layer that prevents introduction of external foreign substances. The first dielectric layer 10 may increase a bonding force between the base substrate BS and a semiconductor pattern SM (and/or a conductive pattern) of the circuit layer DP-CL. The first dielectric layer 10 may include at least one selected from a silicon oxide layer and a silicon nitride layer. In an embodiment, the first dielectric layer 10 may include at least one oxide layer (e.g., silicon oxide layer) and at least one nitride layer (e.g., silicon nitride layer) that are alternately stacked.

In an embodiment, the pixel (see PX of FIG. 4) may be disposed on the base substrate BS. The pixel (see PX of FIG. 4) may be disposed corresponding to a display region DA of the first base region AA1. The pixel (see PX of FIG. 4) may include a transistor TR and a light-emitting element OL.

In an embodiment, the transistor TR may include a semiconductor pattern SM and a gate electrode GE. The semiconductor pattern SM may be disposed on the first dielectric layer 10. The semiconductor pattern SM may include a channel S1, a source S2, and a drain S3. The semiconductor pattern SM may include a silicon semiconductor, such as a monocrystalline silicon semiconductor, a polycrystalline silicon semiconductor, or an amorphous silicon semiconductor. The present invention is not limited thereto, and the semiconductor pattern SM may include an oxide semiconductor. The semiconductor pattern SM according to an embodiment may be formed of various materials as long as the materials have semiconductor properties, and the invention is not limited thereto.

In an embodiment, the semiconductor pattern SM may include a plurality of regions whose electrical properties are different in accordance with whether or not the semiconductor pattern SM is doped or reduced. For example, the semiconductor pattern SM may include a region whose conductivity is large due to doping or oxidation of metal oxide, and the region having high conductivity may serve as a signal line or an electrode of the transistor TR. This region may correspond to the source S2 and the drain S3 of the transistor TR. The semiconductor pattern SM may include a region which is undoped and whose conductivity is relatively small, and this region may correspond to the channel S1 (or active) of the transistor TR.

In an embodiment, the second dielectric layer 20 may be disposed on the first dielectric layer 10 to cover the semiconductor pattern SM. The gate electrode GE may be disposed on the second dielectric layer 20. The second dielectric layer 20 may be disposed between the gate electrode GE and the semiconductor pattern SM of the transistor TR. When viewed in a plan view, the gate electrode GE may overlap the channel S1 of the semiconductor pattern SM. The gate electrode GE may serve as a mask in a process where the semiconductor pattern SM is doped. The gate electrode GE may include molybdenum (Mo) having heatproof, a molybdenum-containing alloy, or a titanium-containing alloy, but the invention is not limited thereto.

In an embodiment, the transistor TR has a configuration illustrated by way of example in FIG. 9, and the source S2 and the drain S3 of the transistor TR may be electrodes independently formed from the semiconductor pattern SM. In this case, the source S2 and the drain S3 may be in contact with the semiconductor pattern SM or may penetrate a dielectric layer to be coupled to the semiconductor pattern SM. In addition, the gate electrode GE may be disposed below the semiconductor pattern SM. According to an embodiment, the transistor TR may be formed having various forms, and the invention is not limited to a certain embodiment.

In an embodiment, the second dielectric layer 20 and the third to sixth dielectric layers 30 to 60, respectively, which will be discussed below may include at least one selected from an inorganic layer and an organic layer. For example, the inorganic layer may include at least one selected from aluminum oxide, titanium oxide, silicon oxynitride, zirconium oxide, and hafnium oxide. The organic layer may include at least one selected from an acryl-based resin, a methacrylic-based resin, polyisoprene, a vinyl-based resin, an epoxy-based resin, a urethane-based resin, a cellulose-based resin, a siloxane-based resin, a polyamide-based resin, and a perylene-based resin.

In an embodiment, the third dielectric layer 30 may be disposed on the second dielectric layer 20 to cover the gate electrode GE. The upper electrode UE may be disposed on the third dielectric layer 30. The upper electrode UE, when viewed in a plan view, may overlap the gate electrode GE, and a capacitor may be constituted by the gate electrode GE and the upper electrode UE that overlap each other.

In an embodiment, the fourth dielectric layer 40 may be disposed on the third dielectric layer 30 to cover the upper electrode UE. The connection electrodes CN1 and CN2 may include a first connection electrode CN1 and a second connection electrode CN2. The first connection electrode CN1 may be disposed on the fourth dielectric layer 40. The fifth dielectric layer 50 may be disposed on the fourth dielectric layer 40 to cover the first connection electrode CN1. The second connection electrode CN2 may be disposed on the fifth dielectric layer 50. The sixth dielectric layer 60 may be disposed on the fifth dielectric layer 50 to cover the second connection electrode CN2. In an embodiment, at least one selected from the fifth dielectric layer 50 and the sixth dielectric layer 60 may include an organic layer and may provide a flat top surface while covering a step difference between components disposed there below.

In an embodiment, the first connection electrode CN1 may be electrically connected to the semiconductor pattern SM through a contact hole that penetrates the second to fourth dielectric layers 20 to 40. The second connection electrode CN2 may be electrically connected to the first connection electrode CN1 through a contact hole that penetrates the fifth dielectric layer 50.

In an embodiment, each of the first and second connection electrodes CN1 and CN2, respectively, may include a conductive material. Each of the first and second connection electrodes CN1 and CN2, respectively, may include gold, silver, copper, aluminum, platinum, molybdenum, titanium, or any alloy thereof. At least one selected from the first and second connection electrodes CN1 and CN2, respectively, may include conductive layers having a multi-layered structure. For example, at least one selected from the first and second connection electrodes CN1 and CN2, respectively, may include a tri-layered structure of titanium/aluminum/titanium. The invention, however, is not limited thereto.

At least one selected from the first and second connection electrodes CN1 and CN2 may be omitted, in accordance with an embodiment of the circuit layer DP-CL. In accordance with another embodiment of the circuit layer DP-CL, an additional connection electrode may further be disposed to connect the transistor TR to the light-emitting element OL. According to the number of dielectric layers disposed between the light-emitting element OL and the transistor TR, an electrical connection type between the light-emitting element OL and the transistor TR may be variously changed, and the invention is not limited to a certain embodiment.

In an embodiment, the display element layer DP-OL may include a light-emitting element OL and a pixel definition layer PDL. The light-emitting element OL and the pixel definition layer PDL may be disposed on the sixth dielectric layer 60. The light-emitting element OL may include a first electrode AE, an emission layer EM, and a second electrode CE.

In an embodiment, the first electrode AE may be electrically connected to the second connection electrode CN2 through a contact hole that penetrates the sixth dielectric layer 60. The first electrode AE may be electrically connected to the transistor TR through the first and second connection electrodes CN1 and CN2, respectively.

In an embodiment, the pixel definition layer PDL may have a pixel opening PX-OP that exposes at least a portion of the first electrode AE. The first electrode AE may have an area exposed from the pixel definition layer PDL, and the exposed area may correspond to an emission region. The pixel definition layer PDL may include an inorganic layer, an organic layer, or a composite material layer. In an embodiment, the pixel definition layer PDL may further include a black pigment or a black dye.

In an embodiment, the emission layer EM may be disposed on the first electrode AE. The emission layer EM may provide light having a certain color. The emission layer EM may be disposed to correspond to the pixel opening PX-OP defined in the pixel definition layer PDL. The light-emitting element OL and the pixel opening PX-OP may each be provided in plural, and the emission layers EM of the light-emitting elements OL may be provided in the form of patterns that are disposed corresponding to the pixel openings PX-OP and are spaced apart from each other. The invention, however, is not limited thereto, and the emission layers EM of the light-emitting elements OL may be formed as a common layer.

In an embodiment, the second electrode CE may be disposed on the emission layer EM and the pixel definition layer PDL. The second electrode CE may be provided as a common electrode that are disposed in common on the pixels (see PX of FIG. 4).

In an embodiment, the light-emitting element OL may further include at least one selected from a hole control region disposed between the first electrode AE and the emission layer EM and an electron control region disposed between the emission layer EM and the second electrode CE. The hole control region may include at least one selected from a hole generation layer, a hole transport layer, and an electron block layer, and the electron control region may include at least one selected from an electron generation layer, an electron transport layer, and a hole block layer.

In an embodiment, the encapsulation layer ECL may be disposed on the display element layer DP-OL. The encapsulation layer ECL may be disposed on the light-emitting element OL and the pixel definition layer PDL, thereby encapsulating the light-emitting element OL. The encapsulation layer ECL may include at least one selected from an inorganic layer and an organic layer. In an embodiment, the encapsulation layer ECL may include a first inorganic layer EN1, a second inorganic layer EN3, and an organic layer EN2 disposed between the first and second inorganic layers EN1 and EN3, respectively. However, a configuration of the encapsulation layer ECL is not limited thereto as long as the encapsulation layer ECL can encapsulate the light-emitting element OL.

In an embodiment, the first inorganic layer EN1 may be disposed on the second electrode CE, and the organic layer EN2 and the second inorganic layer EN3 may be sequentially disposed on the first inorganic layer EN1 in a thickness direction of the display panel DP. The first and second inorganic layers EN1 and EN3, respectively, may protect the light-emitting element OL against moisture and/or oxygen that are externally introduced. Each of the first and second inorganic layers EN1 and EN3, respectively, may include at least one selected from silicon nitride, silicon oxynitride, silicon oxide, titanium oxide, and aluminum oxide. However, the material of the first and second inorganic layers EN1 and EN3 is not limited thereto. The organic layer EN2 may prevent introduction of foreign substances into the light-emitting element OL and may cover a step difference between components disposed below the organic layer EN2. For example, the organic layer EN2 may include an acryl-based organic material. However, the material of the organic layer EN2 is not limited to the example above.

In an embodiment, the input sensing unit ISP may be disposed on the display panel DP. The input sensing unit ISP may include a base layer IL1, a first sensing dielectric layer IL2, a second sensing dielectric layer IL3, a first sensing conductive layer CL1, and a second sensing conductive layer CL2. The description in FIG. 3 may be identically applied to each component.

In an embodiment, the base layer IL1 may be in contact with an uppermost portion (or layer) of the encapsulation layer ECL. For example, the base layer IL1 may be in contact with the second inorganic layer EN3 of the encapsulation layer ECL. The base layer IL1 of the input sensing unit ISP may be directly formed on a base surface provided from the encapsulation layer ECL. The invention, however, is not limited thereto, and the base layer IL1 may be omitted, and in this case the first sensing conductive layer CL1 of the input sensing unit ISP may be in contact with the encapsulation layer ECL.

In an embodiment, the first sensing conductive layer CL1 may be disposed on the base layer IL1, and the second sensing conductive layer CL2 may be disposed on the first sensing dielectric layer IL2. The first sensing conductive layer CL1 and the second sensing conductive layer CL2 may constitute a sensing electrode TE. The sensing electrode TE may correspond to one of the first and second sensing electrodes (see TEX and TEY, respectively, of FIG. 5). The first sensing conductive layer CL1 may include a connection pattern BPC of the sensing electrode TE, and the second sensing conductive layer CL2 may include a sensing pattern SP of the sensing electrode TE. The invention, however, is not limited thereto, and the first sensing conductive layer CL1 may include a sensing pattern SP, and the second sensing conductive layer CL2 may include a connection pattern BPC.

In an embodiment, the connection pattern BPC may correspond to the first connection pattern (see BPC1 of FIG. 5) or the second connection pattern (see BPC2 of FIG. 2), and the sensing pattern SP may correspond to the first sensing pattern (see SP1 of FIG. 5) or the second sensing pattern (see SP2 of FIG. 5). The connection pattern BPC may be located at a different layer from that of the sensing pattern SP and may be coupled to the sensing pattern SP through a contact hole that penetrates the first sensing dielectric layer IL2. The invention, however, is not limited thereto, and the connection pattern BPC and the sensing pattern SP may be located at the same layer to form a single unitary piece.

In an embodiment, the sensing electrode TE may be a mesh-type pattern, and may be disposed to correspond to a region where the pixel definition layer PDL is disposed. The invention, however, is not limited thereto, and the sensing electrode TE may be provided in the form of a single shape that overlaps the light-emitting element OL, and in this case, the sensing electrode TE may include a transparent conductive material.

In an embodiment, the second sensing dielectric layer IL3 may be disposed on the first sensing dielectric layer IL2. The second sensing dielectric layer IL3 may cover the second sensing conductive layer CL2. The second sensing dielectric layer IL3 may cover the sensing pattern SP.

In an embodiment, on the base substrate BS, the first dielectric layer 10 and the second dielectric layer 20 may extend from the first base region AA1 to reside on the second base region AA2. The first pad electrode PD1 and the second pad electrode PD2 may be disposed on the second base region AA2. The first pad electrode PD1 and the second pad electrode PD2 may be disposed on the second dielectric layer 20. The first pad electrode PD1 may be disposed on the first sub-pad region PA1-1, and the second pad electrode PD2 may be disposed on the second sub-pad region PA1-2. The first pad electrode PD1 may be disposed closer than the second pad electrode PD2 to the display region DA in the first base region AA1.

In an embodiment, each of the first and second pad electrodes PD1 and PD2, respectively, may include a plurality of conductive patterns CP1, CP2, CP3, and CP4 and dielectric patterns PP that are disposed along a thickness direction thereof. The second dielectric layer 20 may be provided on the first conductive patterns CP1 of the first and second pad electrodes PD1 and PD2, respectively.

In an embodiment, the first conductive patterns CP1 of the first and second pad electrodes PD1 and PD2, respectively, may be formed by the same process for forming the gate electrode GE of the transistor TR. For example, a deposition process such as sputtering or chemical vapor deposition may be employed to form a conductive layer on the second dielectric layer 20, and then the conductive layer may be patterned to form the gate electrode GE and the first conductive patterns CP1 of the first and second pad electrodes PD1 and PD2, respectively. The first conductive patterns CP1 of the first and second pad electrodes PD1 and PD2, respectively, may be located at the same layer as that of the gate electrode GE of the transistor TR, and may include the same material as that of the gate electrode GE of the transistor TR.

In an embodiment, the third dielectric layer 30 and the fourth dielectric layer 40 may extend from the first base region AA1 to reside on the second base region AA2. The third dielectric layer 30 and the fourth dielectric layer 40 may have first through holes CT1 that expose top surfaces of the first conductive patterns CP1 included in the first and second pad electrodes PD1 and PD2, respectively. The first through holes CT1 of the third and fourth dielectric layers 30 and 40 may be formed by sequentially depositing dielectric layers on the first base region AA1 and the second base region AA2, and then etching the dielectric layers to partially expose the top surfaces of the first conductive patterns CP1 included in the first and second pad electrodes PD1 and PD2, respectively.

In an embodiment, as illustrated in FIG. 9, at least a portion of the dielectric layers on the first base region AA1 may be disposed on the second base region AA2, and a stack structure of the dielectric layers on the second base region AA2 is not limited thereto.

In an embodiment, each of the second conductive patterns CP2 of the first and second pad electrodes PD1 and PD2, respectively, may be disposed on the top surface of a corresponding one of the exposed first conductive patterns CP1. The second conductive patterns CP2 may be correspondingly in contact with the first conductive patterns CP1. A portion of the second conductive patterns CP2 may be disposed on the fourth dielectric layer 40. For example, a portion of the second conductive patterns CP2 may be disposed on the fourth dielectric layer 40 while covering inner lateral surfaces of the third and fourth dielectric layers 30 and 40 exposed by the first through hole CT1.

In an embodiment, the second conductive patterns CP2 of the first and second pad electrodes PD1 and PD2, respectively, may be formed by the same process for forming one of conductive electrodes in the circuit layer DP-CL. For example, the second conductive patterns CP2 of the first and second pad electrodes PD1 and PD2, respectively, may be formed by the same process for forming the first connection electrode CN1. A deposition process such as sputtering or chemical vapor deposition may be employed to form a conductive layer on the fourth dielectric layer 40, and then the conductive layer may be patterned to form the first connection electrode CN1 and the second conductive patterns CP2 of the first and second pad electrodes PD1 and PD2, respectively. The second conductive patterns CP2 of the first and second pad electrodes PD1 and PD2, respectively, may be located at the same layer as that of the first connection electrode CN1, and may include the same material as that of the first connection electrode CN1.

In an embodiment, the dielectric patterns PP may be disposed on the second conductive patterns CP2. The dielectric patterns PP may be disposed in second through holes CT2 defined by the second conductive patterns CP2. The dielectric patterns PP may protrude more than surroundings of the first and second pad electrodes PD1 and PD2, respectively. The dielectric patterns PP may have their top surfaces located at a height higher than that of a top surface of the fourth dielectric layer 40 and that of top surfaces of the second conductive patterns CP2. The dielectric patterns PP may define a protrusion.

In an embodiment, the dielectric patterns PP may include a polymer, but the invention is not limited thereto and may include any material as long as the material can define the protrusion.

In an embodiment, the dielectric patterns PP may have their flat top surfaces. The invention, however, is not limited thereto, and the top surfaces of the dielectric patterns PP may have various shapes.

In an embodiment, the third conductive patterns CP3 of the first and second pad electrodes PD1 and PD2, respectively, may be disposed on the second conductive patterns CP2. The third conductive patterns CP3 may be disposed corresponding to shapes of the top surfaces of the dielectric patterns PP. For example, the third conductive patterns CP3 may be disposed on the flat top surfaces of the dielectric patterns PP and may have their flat top surfaces. The third conductive patterns CP3 may cover the second conductive patterns CP2 and the dielectric patterns PP. The third conductive patterns CP3 may be in contact with the second conductive patterns CP2.

In an embodiment, as the third conductive patterns CP3 are disposed on the dielectric patterns PP, the third conductive patterns CP3 may protrude more than surroundings of the first and second pad electrodes PD1 and PD2, respectively. The top surfaces of the third conductive patterns CP3 may be located at a height higher than that of the top surface of the fourth dielectric layer 40.

In an embodiment, the third conductive patterns CP3 may be formed by the same process for forming one of the conductive electrodes in the circuit layer DP-CL. For example, the third conductive patterns CP3 of the first and second pad electrodes PD1 and PD2, respectively, may be formed by the same process for forming the second connection electrode CN2. The fifth dielectric layer 50 disposed below the second connection electrode CN2 may be opened corresponding to a region where the first and second pad electrodes PD1 and PD2, respectively, are disposed. For example, the fifth dielectric layer 50 may not be disposed on the second conductive patterns CP2 of the first and second pad electrodes PD1 and PD2, respectively, and a portion of a conductive layer deposited by a deposition process, such as sputtering or chemical vapor deposition, on the fifth dielectric layer 50 may be in contact with the dielectric patterns PP. After a conductive layer is formed on the fifth dielectric layer 50, the conductive layer may be patterned to form the third conductive patterns CP3 and the second connection electrode CN2. The third conductive patterns CP3 and the second connection electrode CN2 may be disposed on the same layer and may include the same material.

In an embodiment, the base layer IL1 of the input sensing unit ISP may extend from the first base region AA1 to reside on the second base region AA2. The base layer IL1 disposed on the second base region AA2 may be defined as a first dielectric layer IF1. For example, the base layer IL1 disposed on the first base region AA1 and the first dielectric layer IF1 disposed on the second base region AA2 may be a unitary dielectric layer. The invention, however, is not limited thereto, and the base layer IL1 and the first sensing dielectric layer IL2 of the input sensing unit ISP may all extend from the first base region AA1 to reside on the second base region AA2. In this case, the base layer IL1 and the first sensing dielectric layer IL2 stacked on the second base region AA2 may correspond to the first dielectric layer IF1.

In an embodiment, the first dielectric layer IF1 may be disposed on the first sub-pad region PA1-1 and the second sub-pad region PA1-2. The first dielectric layer IF1 may be formed by the same process for forming the base layer IL1 included in the input sensing unit ISP. For example, a deposition process such as chemical vapor deposition may be employed to form a dielectric layer on the first and second base regions AA1 and AA2, respectively, and then the dielectric layer may be etched or patterned to form the base layer IL1 and the first dielectric layer IF1.

In an embodiment, the first dielectric layer IF1 may include an inorganic material and may prevent introduction of moisture or oxygen. For example, the first dielectric layer IF1 may include at least one selected from aluminum oxide, titanium oxide, silicon oxide, silicon oxynitride, zirconium oxide, and hafnium oxide. However, the material of the first dielectric layer IF1 is not limited to the example above.

In an embodiment, the first dielectric layer IF1 may define a plurality of openings OP. The openings OP of the first dielectric layer IF1 may expose the top surface of the third conductive pattern CP3 that covers the dielectric pattern PP and protrudes by the dielectric pattern PP.

In an embodiment, the fourth conductive patterns CP4 of the first and second pad electrodes PD1 and PD2, respectively, may be disposed corresponding to shapes of the top surfaces of the third conductive patterns CP3 exposed from the first dielectric layer IF1. The fourth conductive patterns CP4 may be disposed along the top surfaces of the third conductive patterns CP3. For example, the fourth conductive patterns CP4 disposed on the flat top surfaces of the third conductive patterns CP3 may have their flat top surfaces.

In an embodiment, the fourth conductive patterns CP4 may be in contact with the third conductive patterns CP3. The fourth conductive patterns CP4 may extend from the top surfaces of the third conductive patterns CP3 to reside on a portion of the first dielectric layer IF1.

In an embodiment, as the fourth conductive patterns CP4 are disposed on the dielectric patterns PP, the fourth conductive patterns CP4 may protrude more than surroundings of the first and second pad electrodes PD1 and PD2, respectively. The fourth conductive patterns CP4 may have their top surfaces disposed at a height higher than of the top surface of the fourth dielectric layer 40.

In an embodiment, the fourth conductive patterns CP4 of the first and second pad electrodes PD1 and PD2, respectively, may be formed by the same process for forming one of the conductive layers of the input sensing unit ISP. For example, the fourth conductive patterns CP4 may be formed by the same process for forming the first sensing conductive layer CL1 or the second sensing conductive layer CL2. For example, after the formation of the base layer IL1 and the first dielectric layer IF1, a deposition process such as sputtering or chemical vapor deposition may be employed to form a conductive layer on the base layer IL1 and the first dielectric layer IF1, and then the conductive layer may be patterned to form the first sensing conductive layer CL1 and the fourth conductive patterns CP4. The fourth conductive patterns CP4 may include the same material as that of the first sensing conductive layer CL1 or the second sensing conductive layer CL2.

In an embodiment, the second sensing dielectric layer IL3 of the input sensing unit ISP may be disposed on the first base region AA1 and the second base region AA2. The second sensing dielectric layer IL3 disposed on the second base region AA2 may be defined as a second dielectric layer IF2. For example, the second sensing dielectric layer IL3 disposed on the first base region AA1 and the second dielectric layer IF2 disposed on the second base region AA2 may be a unitary dielectric layer.

In an embodiment, the second dielectric layer IF2 may be disposed on the fourth conductive patterns CP4. The second sensing dielectric layer IL3 may cover the fourth conductive patterns CP4 of the first and second pad electrodes PD1 and PD2, respectively. The second dielectric layer IF2 may be disposed along the top surfaces of the fourth conductive patterns CP4. For example, the second dielectric layer IF2 may be disposed on the flat top surfaces of the fourth conductive patterns CP4 and may have a flat top surface. The second dielectric layer IF2 may be disposed on the fourth dielectric layer 40.

In an embodiment, the second dielectric layer IF2 may be disposed on the first sub-pad region PA1-1 and the second sub-pad region PA1-2. The second dielectric layer IF2 may be formed by the same process for forming the second sensing dielectric layer IL3 included in the input sensing unit ISP. For example, a deposition process such as chemical vapor deposition may be employed to form the second sensing dielectric layer IL3 and the second dielectric layer IF2 on the first and second base regions AA1 and AA2, respectively.

In an embodiment, the second dielectric layer IF2 may be disposed on the dielectric patterns PP. A portion of the second dielectric layer IF2 that overlaps the dielectric patterns PP may protrude more than a portion of the second dielectric layer IF2 disposed around the first and second pad electrodes PD1 and PD2, respectively. The top surface of the second dielectric layer IF2 that overlaps the dielectric patterns PP may be located at a height that is higher than that of the top surface of the second dielectric layer IF2 disposed around the first and second pad electrodes PD1 and PD2, respectively. For example, a thickness of the second dielectric layer IF2 may range from about 10 nanometers to about 30 nanometers.

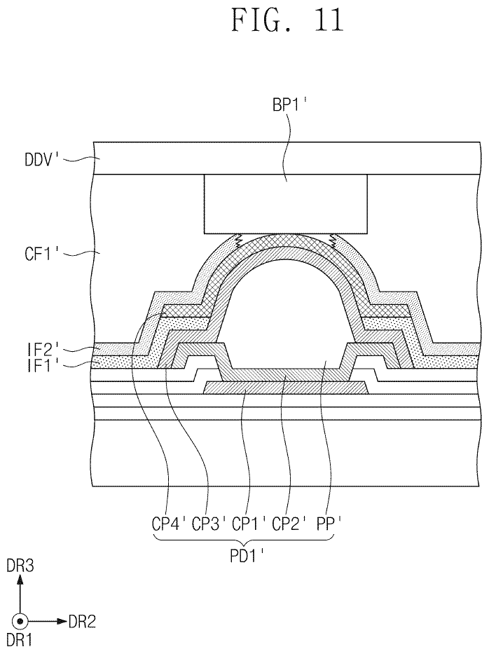

FIG. 10 illustrates a cross-sectional view showing a bonding between a first pad electrode and the data driver depicted in FIG. 6, according to an embodiment. FIG. 11 illustrates a cross-sectional view showing a first pad electrode and a data driver in a comparative example, according to an embodiment.

FIG. 10 shows a cross-sectional view taken along line I-I′ of FIG. 6, according to an embodiment.

In an embodiment, the data driver DDV, the first pad electrode PD1, the base substrate BS, the first dielectric layer IF1, the second dielectric layer IF2, and the first to fourth dielectric layers 10 to 40, respectively, of FIG. 10 may be respectively the same as the data driver DDV of FIG. 6, the first pad electrode PD1, the base substrate BS, the first dielectric layer IF1, the second dielectric layer IF2, and the first to fourth dielectric layers 10 to 40, respectively, of FIG. 9, and thus a description thereof will be omitted or abridged.

In an embodiment, for convenience of description, the following will describe a bonding between the first pad electrode PD1 and the first bump electrode BP1, and this may also be substantially identically applied to a bonding between the second pad electrode (see PD2 of FIG. 6) and the second bump pad (see BP2 of FIG. 6) and a bonding between the flexible circuit board (see FCB of FIG. 6) and the display pads (see D-PD of FIG. 6).

In an embodiment, the first adhesive layer CF1 will be discussed below in the interest of convenience of explanation, but the invention is not limited thereto and the second adhesive layer (see CF2 of FIG. 6) may have the same configuration as that of the first adhesive layer CF1.

In an embodiment and referring to FIG. 10, the first adhesive layer CF1 may include a plurality of nano-conductive particles NCB and an adhesive resin SR. The adhesive resin SR may include a synthetic resin having an adhesive property. The nano-conductive particles NCB may be uniformly distributed in the adhesive resin SR. For example, the nano-conductive particles NCB may each have a spherical shape. The nano-conductive particles NCB may each have a diameter of about 50 nanometers to about 100 nanometers. For example, the nano-conductive particles NCB may be one of chromium and molybdenum.

In an embodiment, the data driver DDV and the display panel (see DP of FIG. 6) may be bonded to each other through the first adhesive layer CF1. When the data driver DDV and the display panel (see DP of FIG. 6) are bonded to each other, the nano-conductive particles NCB may be disposed between the first bump electrode BP1 and the first pad electrode PD1. The first bump electrode BP1 and the first pad electrode PD1 may be electrically connected to each other.

In an embodiment, when the first bump electrode BP1 moves adjacent to the first pad electrode PD1, the nano-conductive particles NCB may be in contact with a bottom surface of the first bump electrode BP1. When the first bump electrode BP1 moves toward the first pad electrode PD1, the nano-conductive particles NCB may also move toward the first bump electrode BP1.

In an embodiment, although not shown, when the nano-conductive particles NCB are disposed on the second dielectric layer IF2, the first bump electrode BP1 may apply a force to the nano-conductive particles NCB. When a force is applied to the nano-conductive particles NCB, the nano-conductive particles NCB may penetrate the second dielectric layer IF2. The penetrating nano-conductive particles NCB may be surrounded by the second dielectric layer IF2. The nano-conductive particles NCB may penetrate the second dielectric layer IF2 to contact the fourth conductive pattern CP4.

In an embodiment, the diameter of the nano-conductive particles NCB may be greater than a thickness of the second dielectric layer IF2. Thus, the nano-conductive particles NCB may contact the fourth conductive pattern CP4 while maintaining a state of being in contact with the first bump electrode BP1. As the nano-conductive particles NCB are in contact with both of the first bump electrode BP1 and the fourth conductive pattern CP4, the first bump electrode BP1 and the fourth conductive pattern CP4 may be electrically connected to each other. Therefore, the data driver DDV and the display panel (see DP of FIG. 6) may be electrically connected to each other.

In an embodiment and referring to FIG. 11, a data driver DDV′ and a first pad electrode PD1′ may be connected to each other through a first adhesive layer CF1′. In this case, a first bump electrode BP1′ of the data driver DDV′ may move toward the first pad electrode PD1′ and may apply an external force to a second dielectric layer IF2′ of the first pad electrode PD1′. The second dielectric layer IF2′ may be fractured which is provided with a pressure resulting from the external force. A portion of a fourth conductive pattern CP4′ may be outwardly exposed from the second dielectric layer IF2′. The first bump electrode BP1′ may be connected to the fourth conductive pattern CP4′ that is outwardly exposed from the second dielectric layer IF2′.

In an embodiment, the pressure that the first bump electrode BP1′ applies to the first pad electrode PD1′ may be in inverse proportion to a contact area between the first bump electrode BP1′ and the second dielectric layer IF2′. In this sense, the magnitude of pressure may be defined as the magnitude of external force applied per unit area.

In an embodiment, when the first bump electrode BP1′ applies an external force whose magnitude is constant, in order to increase the magnitude of pressure applied from the first bump electrode BP1′ to the first pad electrode PD1′, the first pad electrode PD1′ may be formed to have a curved top surface as illustrated in FIG. 11. It may thus be possible to reduce the contact area between the first bump electrode BP1′ and the second dielectric layer IF2′.

In an embodiment, to allow the first pad electrode PD1′ to have the curved top surface, an additional process may be required after a process in which the second dielectric layer IF2′ is deposited. For example, in the additional process, a photoresist type may be used such that an exposure process is performed to remove a portion of the top surface of the first pad electrode PD1′. As the top surface of the first pad electrode PD1′ is processed, there may be an increase in process time. In addition, when the top surface of the first pad electrode PD1′ experiences an uneven exposure amount, an unnecessary residual layer may be created. There may thus be an occurrence of failure of the first pad electrode PD1′.

In an embodiment and referring to FIG. 10, in the case of the first pad electrode PD1 and the first adhesive layer CF1, the first bump electrode BP1 may apply an external force to the nano-conductive particles NCB disposed on the second dielectric layer IF2.

In an embodiment, the nano-conductive particles NCB may transfer the external force to the second dielectric layer IF2. The nano-conductive particles NCB may deliver the external force to a contact section between the nano-conductive particles NCB and the second dielectric layer IF2. The contact section between the nano-conductive particles NCB and the second dielectric layer IF2 may be contact points between the spherical nano-conductive particles NCB and the flat top surface of the second dielectric layer IF2. The contact section between the nano-conductive particles NCB and the second dielectric layer IF2 may have an area less than the contact area between the first bump electrode BP1′ and the second dielectric layer IF2′ depicted in FIG. 9. There may thus be an increase in pressure that the nano-conductive particles NCB apply to the second dielectric layer IF2. Therefore, the nano-conductive particles NCB may stably penetrate the second dielectric layer IF2 and may be in contact with and electrically connected to the fourth conductive pattern CP4 disposed below the second dielectric layer IF2. Accordingly, there may be improved properties of electrical connection between the first pad electrode PD1 and the first bump electrode BP1.

In addition, in an embodiment, after deposition of the second dielectric layer IF2, no additional process may be required to form a curved top surface of the first pad electrode PD1. For example, when the first pad electrode PD1 is deposited to have a flat top surface, no process may be needed to transform the flat top surface into a curved surface. This, however, is merely exemplary, and even when the first pad electrode PD1 is deposited to have different shapes, no additional process may be required to form a curved top surface.

In an embodiment, as a photoresist type process is not performed, it may be possible to reduce a process time and to prevent the first pad electrode PD1 from failure caused by creation of a residual layer.

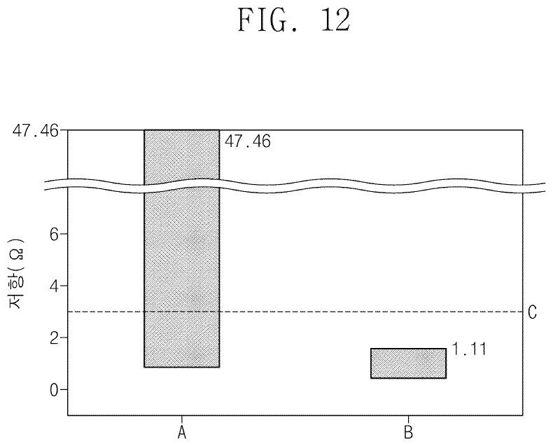

FIG. 12 illustrates a graph showing electric connection properties between a data driver and a display panel, according to an embodiment.

In an embodiment, FIG. 12 illustrates a graph showing a measured result of resistance between an embodiment in which the nano-conductive particles (see NCB of FIG. 10) are not included and an embodiment in which the nano-conductive particles (see NCB of FIG. 10) are included.

For example, a first graph A may show a measured result of resistance of an embodiment in which the nano-conductive particles (see NCB of FIG. 10) are not included. A second graph B may show a measured result of resistance of an embodiment in which the nano-conductive particles (see NCB of FIG. 10) are included.

A dotted line C may be defined as a resistance limit within which it is possible to obtain reliability of bonding between the data driver DDV and the display panel DP depicted in FIG. 6, according to an embodiment.

Referring to FIGS. 6, 10, and 12, in the embodiment showing a result of the first graph A, the second dielectric layer IF2 may have a flat top surface, and thus an increased contact area may be provided between the first bump electrode BP1 and the first pad electrode PD1. There may thus be a reduction in pressure that the first bump electrode BP1 applies to the second dielectric layer IF2, and there may be no fracture of the second dielectric layer IF2. In this embodiment, the first bump electrode BP1 and the first pad electrode PD1 may not be electrically connected to each other, which may result in an increase in resistance. For example, in the embodiment showing a result of the first graph A, a maximum resistance may be about 47.46Ω. There may thus be reduced properties of electrical connection between the data driver DDV and the display panel DP.

In the embodiment showing a result of the second graph B, the nano-conductive particles NCB may apply a large pressure to a top surface of the second dielectric layer IF2. In this embodiment, the second dielectric layer IF2 may be fractured, and the fourth conductive pattern CP4 and the first bump electrode BP1 may be electrically connected to each other through the nano-conductive particles NCB. For example, in the embodiment showing a result of the second graph B, a maximum resistance may be about 1.11Ω. Therefore, the resistance may not exceed a resistance limit capable of obtaining reliability of a bonding between the data driver DDV and the display panel DP. Accordingly, there may be increased properties of electrical connection between the data driver DDV and the display panel DP.

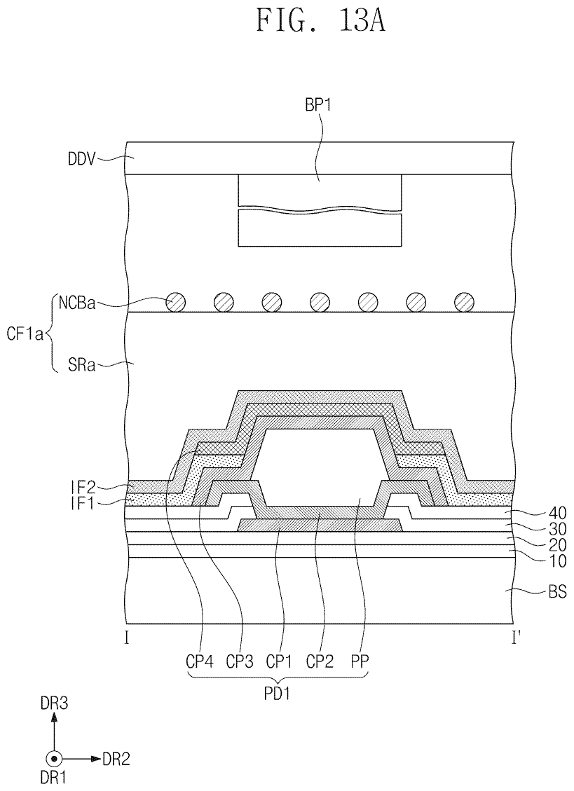

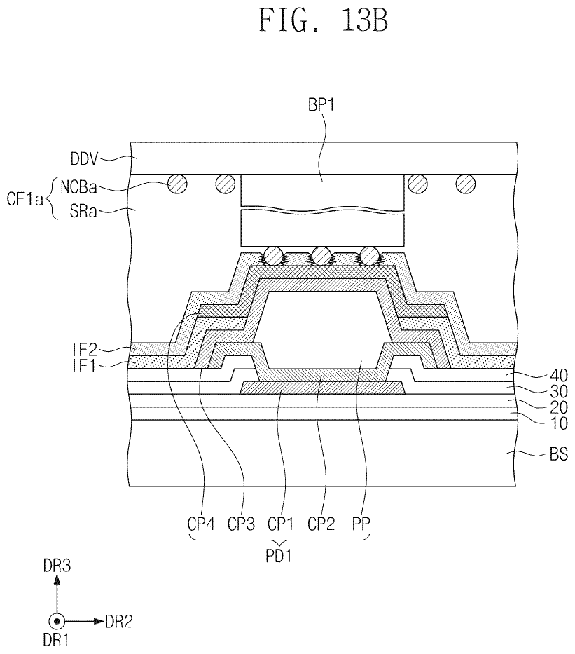

FIGS. 13A and 13B illustrate cross-sectional views showing a first adhesive layer, according to an embodiment.

In an embodiment and referring to FIGS. 13A and 13B, a first adhesive layer CF1a will be exemplarily explained, but the second adhesive layer (see CF2 of FIG. 6) may have the same configuration as that of the first adhesive layer CF1a.

FIGS. 13A and 13B show a cross-sectional view taken along line I-I′ of FIG. 6, according to an embodiment.

In an embodiment, the first pad electrode PD1, the data driver DDV, the base substrate BS, the first dielectric layer IF1, the second dielectric layer IF2, and the first to fourth dielectric layers 10 to 40, respectively, of FIGS. 13A and 13B may be respectively the same as the first pad electrode PD1, the data driver DDV, the base substrate BS, the first dielectric layer IF1, the second dielectric layer IF2, and the first to fourth dielectric layers 10 to 40, respectively, of FIG. 10, and thus a description thereof will be omitted or abridged.

In an embodiment and referring to FIG. 13A, an adhesive resin SRa may be disposed on the first pad electrode PD1. The adhesive resin SRa may cover the first pad electrode PD1. Nano-conductive particles NCBa may be disposed on a top surface of the adhesive resin SRa. The nano-conductive particles NCBa may not be disposed in the adhesive resin SRa. The data driver DDV may be disposed on the first adhesive layer CF1a.

In an embodiment and referring to FIGS. 13A and 13B, the data driver DDV may move in the third direction DR3 toward the first pad electrode PD1. The first bump electrode BP1 may move toward the first pad electrode PD1. The first bump electrode BP1 may be surrounded by the adhesive resin SRa of the first adhesive layer CF1a.

In an embodiment, some of the nano-conductive particles NCBa that do not overlap the first bump electrode BP1 may be disposed on a bottom surface of the data driver DDV. Some of the nano-conductive particles NCBa that overlap the first bump electrode BP1 may move into the adhesive resin SRa. A bottom surface of the first bump electrode BP1 may press the overlapping nano-conductive particles NCBa in the third direction DR3, and thus the overlapping nano-conductive particles NCBa may move into the adhesive resin SRa.

In an embodiment, some of the nano-conductive particles NCBa disposed in the adhesive resin SRa may be disposed between the first bump electrode BP1 and the first pad electrode PD1. The first bump electrode BP1 may apply a pressure to the nano-conductive particles NCBa. The nano-conductive particles NCBa may transfer the pressure to the second dielectric layer IF2. Therefore, the nano-conductive particles NCBa may penetrate the second dielectric layer IF2 to contact the fourth conductive pattern CP4. The first bump electrode BP1 and the first pad electrode PD1 may be electrically connected to each other.

In an embodiment, even though the first pad electrode PD1 has a flat top surface, the nano-conductive particles NCBa may apply a large pressure to the second dielectric layer IF2. This, however, is merely exemplary, and even when the top surface of the first pad electrode PD1 has different shapes, the nano-conductive particles NCBa may apply a large pressure to the top surface of the first pad electrode PD1.

In an embodiment, the nano-conductive particles NCBa may penetrate the second dielectric layer IF2 to come into connection with the fourth conductive pattern CP4. Accordingly, the nano-conductive particles NCBa may increase properties of electrical connection between the first bump electrode BP1 and the first pad electrode PD1.

In addition, according to an embodiment, no additional process may be required to reduce an area of the top surface of the first pad electrode PD1, and thus there may be a reduction in process time for forming the first pad electrode PD1.

According to an embodiment, nano-conductive particles may penetrate a dielectric layer of a pad electrode, and may thus electrically connect the pad electrode to a bump electrode. Therefore, a top surface of the pad electrode may not be limited in terms of shape. In conclusion, no additional process may be required to process the top surface of the pad electrode, and a process time may become reduced.

Moreover, in an embodiment, as nano-conductive balls penetrate the dielectric layer of the pad electrode, increased connection stability may be provided between the pad electrode and the bump electrode, and a low resistance may be securely obtained. As a result, it may be possible to improve properties of electrical connection between the pad electrode and the bump electrode.

Although the invention is described in conjunction with some example embodiments thereof, it would be understood by those skilled in the art that the invention can be modified or changed in various ways without departing from spirit and scope of the invention. Further, the embodiments disclosed herein are not intended to limit the technical spirit and scope of the invention. Accordingly, it will be understood that the invention should not be limited to these embodiments. Moreover, the embodiments or parts of the embodiments may be combined in whole or in part without departing from the scope of the invention.

What is claimed is:

1. A display device, comprising:
a display panel that includes a pad electrode;
a data driver disposed on the display panel, the data driver including a bump electrode that corresponds to the pad electrode; and
an adhesive layer that includes a nano-conductive particle in contact with the pad electrode and the bump electrode,
wherein the pad electrode includes:
a dielectric pattern that protrudes more than surroundings of the pad electrode;
a conductive pattern that covers the dielectric pattern; and
a dielectric layer that covers the conductive pattern,
wherein the nano-conductive particle penetrates the dielectric layer to contact the conductive pattern.

2. The display device of claim 1, wherein a diameter of the nano-conductive particle is in a range of about 50 nanometers to about 100 nanometers.

3. The display device of claim 1, wherein the pad electrode and the bump electrode are electrically connected to each other through the nano-conductive particle.

4. The display device of claim 2, wherein the adhesive layer further includes an adhesive resin, and
wherein the nano-conductive particle includes a plurality of nano-conductive particles which are uniformly distributed in the adhesive resin.

5. The display device of claim 2, wherein the adhesive layer further includes an adhesive resin,
wherein the nano-conductive particle is disposed on a bottom surface of the data driver, and between the pad electrode and the bump electrode.

6. The display device of claim 2, wherein the diameter of the nano-conductive particle is greater than a thickness of the dielectric layer.

7. The display device of claim 6, wherein the thickness of the dielectric layer is in a range of about 10 nanometers to about 30 nanometers.

8. The display device of claim 1, wherein the pad electrode has a flat top surface that faces the bump electrode.

9. The display device of claim 1, wherein the conductive pattern includes:
a first conductive pattern disposed below the dielectric pattern;
a second conductive pattern disposed between the first conductive pattern and the dielectric pattern;
a third conductive pattern, wherein the third conductive pattern covers the dielectric pattern and is connected to the second conductive pattern; and
a fourth conductive pattern disposed on the third conductive pattern,
wherein the dielectric pattern protrudes more than surroundings of the pad electrode, and
wherein the third conductive pattern and the fourth conductive pattern which are disposed on the dielectric pattern protrude more than surroundings of the pad electrode.

10. The display device of claim 1, wherein the data driver further includes an integrated circuit disposed on and connected to the bump electrode.

11. The display device of claim 1, wherein the nano-conductive particle includes one of chromium and molybdenum.

12. A display device, comprising:
a base substrate;
a pad electrode including a plurality of conductive patterns that reside on the base substrate and a dielectric layer that covers the plurality of conductive patterns;
a data driver including a bump electrode that corresponds to the pad electrode; and
an adhesive layer disposed between the pad electrode and the bump electrode, the adhesive layer including a plurality of nano-conductive particles,
wherein the plurality of nano-conductive particles are in contact with the conductive patterns and are surrounded by the dielectric layer.

13. The display device of claim 12, wherein
the plurality of nano-conductive particles penetrate the dielectric layer to come into contact with the conductive patterns,
the plurality of nano-conductive particles are in contact with the bump electrode, and
the bump electrode and the conductive patterns are electrically connected to each other through the plurality of nano-conductive particles.

14. The display device of claim 13, wherein a diameter of each of the plurality of nano-conductive particles is in a range of about 50 nanometers to about 100 nanometers.

15. The display device of claim 14, wherein the adhesive layer further includes an adhesive resin,
wherein the plurality of nano-conductive particles are uniformly distributed in the adhesive resin.

16. The display device of claim 14, wherein the plurality of nano-conductive particles are disposed between a bottom surface of the data driver, the pad electrode, and the bump electrode.

17. The display device of claim 12, wherein the conductive patterns include:
a first conductive pattern;
a second conductive pattern disposed on and connected to the first conductive pattern;
a third conductive pattern disposed on and connected to the second conductive pattern; and
a fourth conductive pattern disposed on and connected to the third conductive pattern,
wherein the dielectric layer is disposed on a top surface of the fourth conductive pattern.

18. The display device of claim 17, wherein the pad electrode further includes a dielectric pattern disposed between the second conductive pattern and the third conductive pattern,
wherein the dielectric pattern causes the third conductive pattern and the fourth conductive pattern to protrude more than surroundings of the pad electrode.

19. The display device of claim 12, wherein a diameter each of the plurality of nano-conductive particles is greater than a thickness of the dielectric layer.

20. The display device of claim 12, wherein the plurality of nano-conductive particles include one of chromium and molybdenum.
